(19) United States
(12) Patent Application Publication
(10) Pub. No.: US 2022/0113361 A1
(43) Pub. Date: Apr. 14, 2022

(54) SYSTEMS AND METHODS FOR PERFORMING MAGNETIC RESONANCE IMAGING

(71) Applicant: PROMAXO, INC., Oakland, CA (US)

(72) Inventors: Aleksandar NACEV, San Francisco, CA (US); Jose ALGARIN, Oakland, CA (US); Pulkit MALIK, Oakland, CA (US); Hongli DONG, Newark, CA (US); Muller GOMES, Oakland, CA (US); Sabareish PANDIAN, San Francisco, CA (US); Dinesh KUMAR, Roseville, CA (US); John NOLTE, Citrus Heights, CA (US); Ram NARAYANAN, San Jose, CA (US)

(73) Assignee: PROMAXO, INC., Oakland, CA (US)

(21) Appl. No.: 17/310,696

(22) PCT Filed: Feb. 24, 2020
(86) PCT No.: PCT/US2020/019530

§ 371 Date: Aug. 18, 2021

Related U.S. Application Data
(60) Provisional application No. 62/809,503, filed on Feb. 22, 2019.
(60) Provisional application No. 62/823,521, filed on Mar. 25, 2019.
(60) Provisional application No. 62/979,332, filed on Feb. 20, 2020.

(51) Int. Cl. G01R 33/38; G01R 33/383; G01R 33/385; G01R 33/54

(52) U.S. Cl. CPC G01R 33/3808; G01R 33/543; G01R 33/385; G01R 33/383

(57) ABSTRACT

In accordance with various embodiments, a magnetic resonance imaging system is provided. In accordance with various embodiments, the system includes a housing having a front surface, a permanent magnet for providing a static magnetic field, a radio N frequency transmit coil, and at least one gradient coil set. In accordance with various embodiments, the radio frequency transmit coil and the at least one gradient coil set are positioned proximate to the front surface. In accordance with various embodiments, the radio frequency transmit coil and the at least one gradient coil set are configured to generate an electromagnetic field in a region of interest. In accordance with various embodiments, the permanent magnet has an aperture through center of the permanent magnet. In accordance with various embodiments, the region of interest resides outside the front surface.

### BACKGROUND

Magnetic resonance imaging (MRI) systems have primarily been focused on leveraging an enclosed form factor. This form factor includes surrounding the imaging region with electromagnetic field producing materials and imaging system components. A typical MRI system includes a cylindrical bore magnet where the patient is placed within the tube of the magnet for imaging. Components, such as radio frequency (RF) transmission (TX) and reception (RX) coils, gradient coils and permanent magnet are positioned accordingly to produce the necessary magnetic field within the tube for imaging the patient.

The majority of current MRI systems thus suffer from multiple disadvantages, some examples of which are provided as follows. First, the footprint for these systems is substantial, often requiring that MRI systems be housed in hospitals or external imaging centers. Second, closed MRI systems make interventions (e.g., image guided interventions such as MRI guided biopsies, treatment planning, robotic surgeries and radiation treatments) much more difficult. Third, the placement of the primary magnet components discussed above to virtually surround the patient, as is the case in most current MRI systems, severely limits the movement of the patient, often causing panic in patients situated inside the MRI system as well as additional burdens during situating or removing the patient to and from within the imaging region. In other current MRI systems, the patient is placed between two large plates to relieve some physical restrictions on patient placement. Regardless, a need exists to provide modern imaging configurations in next generation MRI systems to reduce footprint, allowing for in office MRI procedures across various regions of interest. A need also exists to provide MRI system designs that allow for various image guided interventions. Moreover, a need exists to provide MRI system designs that improve the patient experience and ease at which a patient can be scanned.

### SUMMARY

In accordance with various embodiments, a magnetic resonance imaging system is provided. In accordance with various embodiments, the system includes a housing having a front surface, a permanent magnet for providing a static magnetic field, a radio frequency transmit coil, and a single-sided gradient coil set. In accordance with various embodiments, the radio frequency transmit coil and the single-sided gradient coil set are positioned proximate to the front surface. In accordance with various embodiments, the system includes an electromagnet, a radio frequency receive coil, and a power source. In accordance with various embodiments, the power source is configured to flow current through at least one of the radio frequency transmit coil, the single-sided gradient coil set, or the electromagnet to generate an electromagnetic field in a region of interest. In accordance with various embodiments, the region of interest resides outside the front surface.

In accordance with various embodiments, a magnetic resonance imaging system is provided. In accordance with various embodiments, the system includes a housing having a concave front surface, a permanent magnet for providing a static magnetic field, a radio frequency transmit coil, and at least one gradient coil set. In accordance with various embodiments, the radio frequency transmit coil and the at least one gradient coil set are positioned proximate to the concave front surface. In accordance with various embodiments, the radio frequency transmit coil and the at least one gradient coil set are configured to generate an electromagnetic field in a region of interest. In accordance with various embodiments, the region of interest resides outside the concave front surface. In accordance with various embodiments, the system includes a radio frequency receive coil for detecting signal in the region of interest.

In accordance with various embodiments, a method of performing magnetic resonance imaging is provided. The method includes inputting patient parameters into a magnetic resonance imaging system, the system comprising: a housing comprising: a front surface, a permanent magnet for providing a static magnetic field, a radio frequency transmit coil, and a single-sided gradient coil set, wherein the radio frequency transmit coil and the single-sided gradient coil set are positioned proximate to the front surface; an electromagnet; a radio frequency receive coil; and a power source, wherein the power source is configured to flow current through at least one of the radio frequency transmit coil, the single-sided gradient coil set, or the electromagnet to generate an electromagnetic field in a region of interest, wherein the region of interest resides outside the front surface; executing a patient positioning protocol comprising running at least one first scan; running at least one second scan; reviewing the at least one second scan; and determining at least one path for conducting a biopsy based on review of the at least one second scan.

In accordance with various embodiments, a method of performing magnetic resonance imaging is provided. The method includes inputting patient parameters into a magnetic resonance imaging system, the system comprising: a housing comprising: a concave front surface, a permanent magnet for providing a static magnetic field, a radio frequency transmit coil, and at least one gradient coil set, wherein the radio frequency transmit coil and the at least one gradient coil set are positioned proximate to the concave front surface, wherein the radio frequency transmit coil and the at least one gradient coil set are configured to generate an electromagnetic field in a region of interest, wherein the region of interest resides outside the concave front surface; and a radio frequency receive coil for detecting signal in the region of interest; executing a patient positioning protocol comprising running at least one first scan; running at least one second scan; reviewing the at least one second scan; and determining at least one path for conducting a biopsy based on review of the at least one second scan.

In accordance with various embodiments, a method of performing a scan on a magnetic resonance imaging system is provided. The method includes providing a housing comprising: a front surface, a permanent magnet for providing a static magnetic field, a radio frequency transmit coil, and a single-sided gradient coil set, wherein the radio frequency transmit coil and the single-sided gradient coil set are positioned proximate to the front surface; providing an electromagnet; activating at least one of the radio frequency transmit coil, the single-sided gradient coil set, or the electromagnet to generate an electromagnetic field in a region of interest, wherein the region of interest resides outside the front surface; activating a radio frequency receive coil to obtain imaging data; reconstructing obtained imaging data to produce an output image for analysis; and displaying the output image for user review and annotation.

In accordance with various embodiments, a method of performing a scan on a magnetic resonance imaging system is provided. The method includes providing a housing comprising: a concave front surface, a permanent magnet for providing a static magnetic field, a radio frequency transmit coil, and a single-sided gradient coil set, wherein the radio frequency transmit coil and the single-sided gradient coil set are positioned proximate to the front surface; activating at least one of the radio frequency transmit coil and the at least one gradient coil set to generate an electromagnetic field in a region of interest, wherein the region of interest resides outside the concave front surface; activating a radio frequency receive coil to obtain imaging data; reconstructing obtained imaging data to produce an output image for analysis; and displaying the output image for user review and annotation.

These and other aspects and implementations are discussed in detail herein. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1 is a schematic illustration of a magnetic resonance imaging system, in accordance with various embodiments.

FIG. 2A is a schematic illustration of a magnetic resonance imaging system, in accordance with various embodiments.

FIG. 2B illustrates an exploded view of the magnetic resonance imaging system shown in FIG. 2A.

FIG. 2C is a schematic front view of the magnetic resonance imaging system shown in FIG. 2A, in accordance with various embodiments.

FIG. 2D is a schematic side view of the magnetic resonance imaging system shown in FIG. 2A, in accordance with various embodiments.

FIG. 3 is a schematic view of an implementation of a magnetic imaging apparatus, according to various embodiments.

FIG. 4 is a schematic view of an implementation of a magnetic imaging apparatus, according to various embodiments.

FIG. 5 is a schematic front view of a magnetic resonance imaging system 500, according to various embodiments.

FIG. 6A is an example schematic illustration of a radio frequency receive coil (RF-RX) array including individual coil elements, in accordance with various embodiments.

FIG. 6B is an example illustration of a loop coil along with example calculations for a loop coil magnetic field, in accordance with various embodiments.

FIG. 6C is an example X-Y chart illustrating the magnetic field as a function of radius of a loop coil, in accordance with various embodiments disclosed herein.

FIG. 6D is a cross-sectional illustration of a portion of the human body, namely in the area of the prostate.

FIG. 7 is a flowchart for a method of performing magnetic resonance imaging, according to various embodiments.

FIG. 8 is a flowchart for another method of performing magnetic resonance imaging, according to various embodiments.

FIG. 9 is a flowchart for a method of performing a scan on a magnetic resonance imaging system, according to various embodiments.

FIG. 10 is a flowchart for another method of performing a scan on a magnetic resonance imaging system, according to various embodiments.

FIGS. 11A-11X illustrate various positions of patient depending on the type of anatomical scan for imaging in a magnetic resonance imaging system, according to various embodiments.

It is to be understood that the figures are not necessarily drawn to scale, nor are the objects in the figures necessarily drawn to scale in relationship to one another. The figures are depictions that are intended to bring clarity and understanding to various embodiments of apparatuses, systems, and methods disclosed herein. Wherever possible, the same reference numbers will be used throughout the drawings to refer to the same or like parts. Moreover, it should be appreciated that the drawings are not intended to limit the scope of the present teachings in any way.

### DETAILED DESCRIPTION

The following description of various embodiments is exemplary and explanatory only and is not to be construed as limiting or restrictive in any way. Other embodiments, features, objects, and advantages of the present teachings will be apparent from the description and accompanying drawings, and from the claims.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

Unless defined otherwise, all technical and scientific terms used herein have the same meaning as commonly understood by one of ordinary skill in the art to which there various embodiments belong.

All publications mentioned herein are incorporated herein by reference for the purpose of describing and disclosing devices, compositions, formulations and methodologies which are described in the publication and which might be used in connection with the present disclosure.

As used herein, the terms “comprise”, “comprises”, “comprising”, “contain”, “contains”, “containing”, “have”, “having” “include”, “includes”, and “including” and their variants are not intended to be limiting, are inclusive or open-ended and do not exclude additional, unrecited additives, components, integers, elements or method steps. For example, a process, method, system, composition, kit, or apparatus that comprises a list of features is not necessarily limited only to those features but may include other features not expressly listed or inherent to such process, method, system, composition, kit, or apparatus.

As discussed herein, and in accordance with various embodiments, the various systems, and various combinations of features that make up the various system embodiments, can include a magnetic resonance imaging system. In accordance with various embodiments, the magnetic resonance imaging system is a single-sided magnetic resonance imaging system that comprises a magnetic resonance imaging scanner or a magnetic resonance imaging spectrometer. In accordance with various embodiments, the magnetic resonance imaging system can include a magnet assembly for providing a magnetic field required for imaging an anatomical portion of a patient. In accordance with various embodiments, the magnetic resonance imaging system can be configured for imaging in a region of interest which resides outside of the magnet assembly.

Typical magnet resonant assemblies used in modern magnetic resonance imaging systems include, for example, a birdcage coil configuration. A typical birdcage configuration includes, for example, a radio frequency transmission coil that can include two large rings placed on opposite sides of the imaging region (i.e., the region of interest where the patient resides) that are each electrically connected by one or more rungs. Since the imaging signal improves the more the coil surrounds the patient, the birdcage coil is typically configured to encompass a patient so that the signal produced from within the imaging region, i.e., the region of interest where the anatomical target portion of the patient resides, is sufficiently uniform. To improve patient comfort and reduce burdensome movement limitations of the current magnetic resonance imaging systems, the disclosure as described herein generally relates to a magnetic resonance imaging system that includes a single-sided magnetic resonance imaging system and its applications.

As described herein, the disclosed single-sided magnetic resonance imaging system can be configured to image the patient from one side while providing access to the patient from both sides. This is possible due to the single-sided magnetic resonance imaging system that contains an access aperture (also referred to herein as “aperture”, “hole” or “bore”), which is configured to project magnetic fields in the region of interest which resides completely outside of the magnet assembly and the magnetic resonance imaging system. Since not being completely surrounded by the electromagnetic field producing materials and imaging system components as in current state of the art systems, the novel single-sided configuration as described herein offer less restriction in patient movement while reducing unnecessary burden during situating and/or removing of the patient from the magnetic resonance imaging system. In accordance with various embodiments as described herein, the patient would not feel entrapped in the disclosed magnetic resonance imaging system with the placement of the magnet assembly on the side of the patient during imaging. The configuration that enables single-sided or imaging from a side is made possible by the disclosed system components as discussed herein.

In accordance with various embodiments, the various systems, and various combinations of features that make up the various system components and embodiments of the disclosed magnetic resonance imaging system are disclosed herein.

In accordance with various embodiments, a magnetic resonance imaging system is disclosed herein. In accordance with various embodiments, the system includes a housing having a front surface, a permanent magnet for providing a static magnetic field, an access aperture (also referred to herein as “aperture”, “hole” or “bore”) within the permanent magnet assembly, a radio frequency transmit coil, and a single-sided gradient coil set. In accordance with various embodiments, the radio frequency transmit coil and the single-sided gradient coil set are positioned proximate to the front surface. In accordance with various embodiments, the system includes an electromagnet, a radio frequency receive coil, and a power source. In accordance with various embodiments, the power source is configured to flow current through at least one of the radio frequency transmit coil, the single-sided gradient coil set, or the electromagnet to generate an electromagnetic field in a region of interest. In accordance with various embodiments, the region of interest resides outside the front surface.

In accordance with various embodiments, the radio frequency transmit coil and the single-sided gradient coil set are located on the front surface. In accordance with various embodiments, the front surface is a concave surface. In accordance with various embodiments, the permanent magnet has an aperture through center of the permanent magnet. In accordance with various embodiments, the static magnetic field of the permanent magnet ranges from 1 mT to 1 T. In accordance with various embodiments, the static magnetic field of the permanent magnet ranges from 10 mT to 195 mT.

In accordance with various embodiments, the radio frequency transmit coil includes a first ring and a second ring that are connected via one or more capacitors and/or one or more rungs. In accordance with various embodiments, the radio frequency transmit coil is non-planar and oriented to partially surround the region of interest. In accordance with various embodiments, the single-sided gradient coil set is non-planar and oriented to partially surround the region of interest. In accordance with various embodiments, the single-sided gradient coil set is configured to project a magnetic field gradient to the region of interest. In accordance with various embodiments, the single-sided gradient coil set includes one or more first spiral coils at a first position and one or more second spiral coils at a second position, the first position and the second position being located opposite each other about a center region of the single-sided gradient coil set. In accordance with various embodiments, the single-sided gradient coil set has a rise time less than 10 μs.

In accordance with various embodiments, the electromagnet is configured to alter the static magnetic field of the permanent magnet within the region of interest. In accordance with various embodiments, the electromagnet has a magnetic field strength from 10 mT to 1 T. In accordance with various embodiments, the radio frequency receive coil is a flexible coil configured to be affixed to an anatomical portion of a patient for imaging within the region of interest. In accordance with various embodiments, the radio frequency receive coil is in one of a single-loop coil configuration, figure-8 coil configuration, or butterfly coil configuration, wherein the coil is smaller than the region of interest. In accordance with various embodiments, the radio frequency transmit coil and the single-sided gradient coil set are concentric about the region of interest. In accordance with various embodiments, the magnetic resonance imaging system is a single-sided magnetic resonance imaging system that comprises a bore having an opening positioned about a center region of the front surface.

In accordance with various embodiments, a magnetic resonance imaging system is disclosed herein. In accordance with various embodiments, the system includes a housing having a concave front surface, a permanent magnet for providing a static magnetic field, a radio frequency transmit coil, and at least one gradient coil set. In accordance with various embodiments, the radio frequency transmit coil and the at least one gradient coil set are positioned proximate to the concave front surface. In accordance with various embodiments, the radio frequency transmit coil and the at least one gradient coil set are configured to generate an electromagnetic field in a region of interest. In accordance with various embodiments, the region of interest resides outside the concave front surface. In accordance with various embodiments, the system includes a radio frequency receive coil for detecting signal in the region of interest.

In accordance with various embodiments, the radio frequency transmit coil and the single-sided gradient coil set are located on the concave front surface. In accordance with various embodiments, the static magnetic field of the permanent magnet ranges from 1 mT to 1 T. In accordance with various embodiments, the static magnetic field of the permanent magnet ranges from 10 mT to 195 mT. In accordance with various embodiments, the radio frequency transmit coil comprises a first ring and a second ring that are connected via one or more capacitors and/or one or more rungs. In accordance with various embodiments, the radio frequency transmit coil is non-planar and oriented to partially surround the region of interest. In accordance with various embodiments, the at least one gradient coil set is non-planar, single-sided, and oriented to partially surround the region of interest. In accordance with various embodiments, the at least one gradient coil set is configured to project magnetic field gradient in the region of interest.

In accordance with various embodiments, the at least one gradient coil set comprises one or more first spiral coils at a first position and one or more second spiral coils at a second position, the first position and the second position being located opposite each other about a center region of the at least one gradient coil set. In accordance with various embodiments, the at least one gradient coil set has a rise time less than 10 μs. In accordance with various embodiments, the permanent magnet has an aperture through center of the permanent magnet. In accordance with various embodiments, the system further includes an electromagnet configured to alter the static magnetic field of the permanent magnet within the region of interest. In accordance with various embodiments, the electromagnet has a magnetic field strength from 10 mT to 1 T. In accordance with various embodiments, the radio frequency receive coil is a flexible coil configured to be affixed to an anatomical portion of a patient for imaging within the region of interest. In accordance with various embodiments, the radio frequency receive coil is in one of a single-loop coil configuration, figure-8 coil configuration, or butterfly coil configuration, where the coil is smaller than the region of interest.

In accordance with various embodiments, the radio frequency transmit coil and the at least one gradient coil set are concentric about the region of interest. In accordance with various embodiments, the magnetic resonance imaging system is a single-sided magnetic resonance imaging system that comprises a magnetic resonance imaging scanner or a magnetic resonance imaging spectrometer.

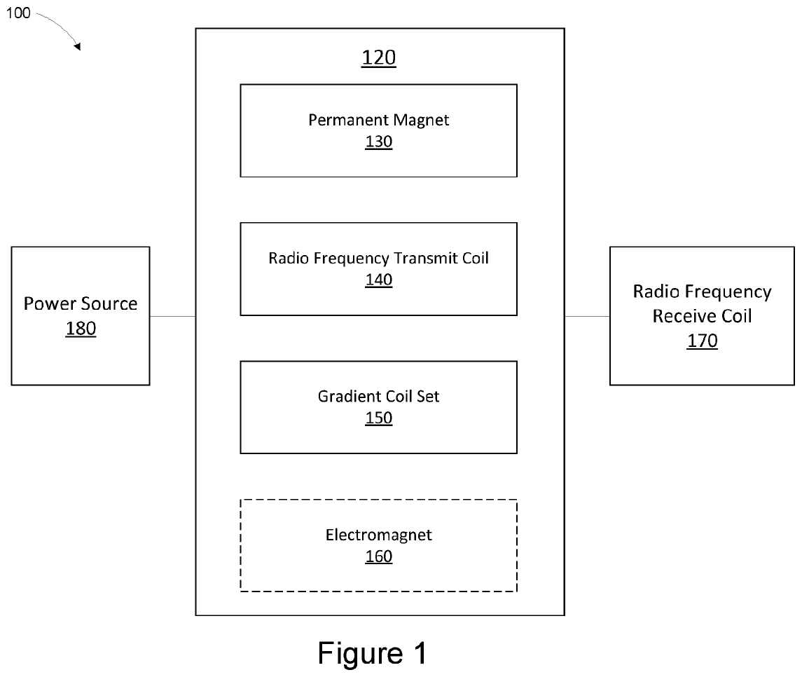

FIG. 1 is a schematic illustration of a magnetic resonance imaging system 100, in accordance with various embodiments. The system 100 includes a housing 120. As shown in FIG. 1, the housing 120 includes a permanent magnet 130, a radio frequency transmit coil 140, a gradient coil set 150, an optional electromagnet 160, a radio frequency receive coil 170, and a power source 180. In accordance with various embodiments, the system 100 can include various electronic components, such as for example, but not limited to a varactor, a PIN diode, a capacitor, or a switch, including a micro-electro-mechanical system (MEMS) switch, a solid state relay, or a mechanical relay. In accordance with various embodiments, the various electronic components listed above can be configured with the radio frequency transmit coil 140.

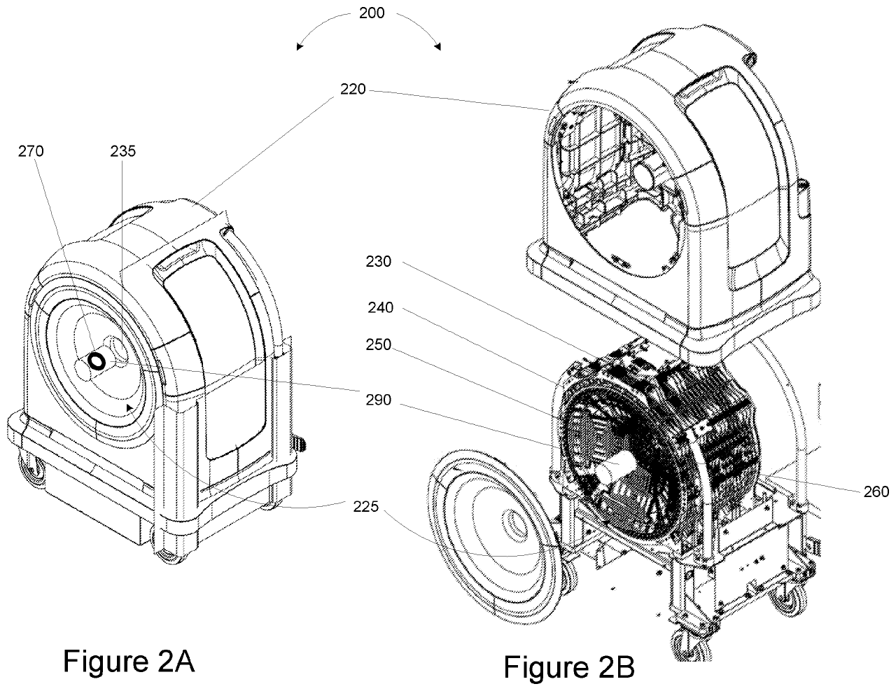

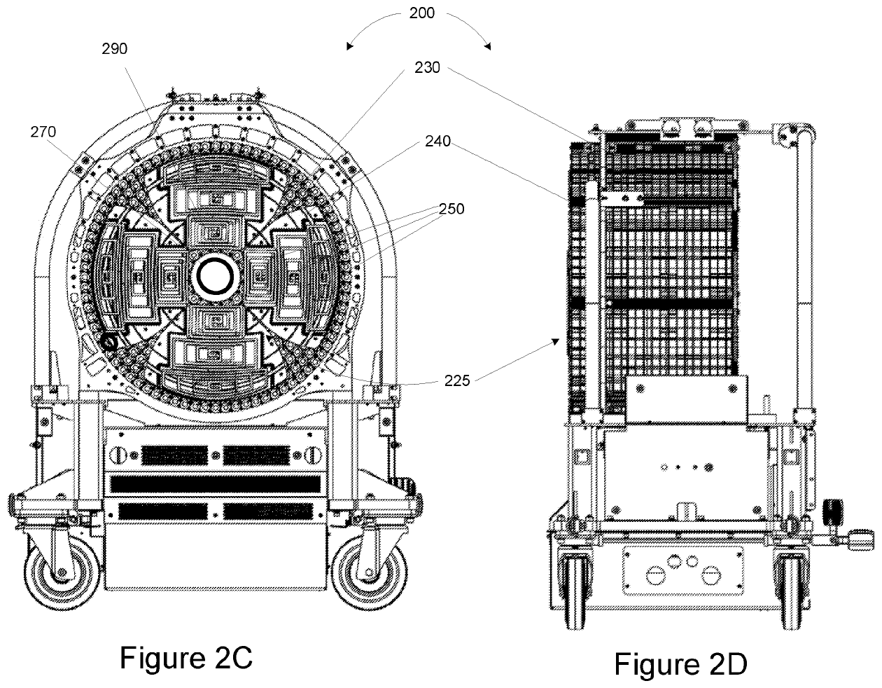

FIG. 2A is a schematic illustration of a magnetic resonance imaging system 200, in accordance with various embodiments. FIG. 2B illustrates an exploded view of the magnetic resonance imaging system 200. FIG. 2C is a schematic front view of the magnetic resonance imaging system 200, in accordance with various embodiments. FIG. 2D is a schematic side view of the magnetic resonance imaging system 200, in accordance with various embodiments. As shown in FIGS. 2A and 2B, the magnetic resonance imaging system 200 includes a housing 220. The housing 220 includes a front surface 225. In accordance with various embodiments, the front surface 225 can be a concave front surface. In accordance with various embodiments, the front surface 225 can be a recessed front surface.

As shown in FIGS. 2A and 2B, the housing 220 includes a permanent magnet 230, a radio frequency transmit coil 240, a gradient coil set 250, an optional electromagnet 260, and a radio frequency receive coil 270. As shown in FIGS. 2C and 2D, the permanent magnet 230 can include a plurality of magnets disposed in an array configuration. The plurality of magnets of the permanent magnet 230 are illustrated to cover an entire surface as shown in the front view of FIG. 2C and illustrated as bars in a horizontal direction as shown in the side view of FIG. 2D. As shown in FIG. 2A, the main permanent magnet might include an access aperture 235 for accessing the patient from multiple sides of the system.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

Permanent Magnet

As discussed herein, and in accordance with various embodiments, the various systems, and various combinations of features that make up the various system embodiments, can include a permanent magnet.

In accordance with various embodiments, the permanent magnet 230 provides a static magnetic field in a region of interest 290 (also referred to herein as “given field of view”). In accordance with various embodiments, the permanent magnet 230 can include a plurality of cylindrical permanent magnets in parallel configuration as shown in FIGS. 2C and 2D. In accordance with various embodiments, the permanent magnet 230 can include any suitable magnetic materials, including but not limited, to rare-earth based magnetic materials, such as for example, Nd-based magnetic materials, and the like. As shown in FIG. 2A, the main permanent magnet might include an access aperture 235 for accessing the patient from multiple sides of the system.

In accordance with various embodiments, the static magnetic field of the permanent magnet 230 may vary from about 50 mT to about 60 mT, about 45 mT to about 65 mT, about 40 mT to about 70 mT, about 35 mT to about 75 mT, about 30 mT to about 80 mT, about 25 mT to about 85 mT, about 20 mT to about 90 mT, about 15 mT to about 95 mT and about 10 mT to about 100 mT to a given field of view. The magnetic field may also vary from about 10 mT to about 15 mT, about 15 mT to about 20 mT, about 20 mT to about 25 mT, about 25 mT to about 30 mT, about 30 mT to about 35 mT, about 35 mT to about 40 mT, about 40 mT to about 45 mT, about 45 mT to about 50 mT, about 50 mT to about 55 mT, about 55 mT to about 60 mT, about 60 mT to about 65 mT, about 65 mT to about 70 mT, about 70 mT to about 75 mT, about 75 mT to about 80 mT, about 80 mT to about 85 mT, about 85 mT to about 90 mT, about 90 mT to about 95 mT, and about 95 mT to about 100 mT. In accordance with various embodiments, the static magnetic field of the permanent magnet 230 may also vary from about 1 mT to about 1 T, about 10 mT to about 195 mT, about 15 mT to about 900 mT, about 20 mT to about 800 mT, about 25 mT to about 700 mT, about 30 mT to about 600 mT, about 35 mT to about 500 mT, about 40 mT to about 400 mT, about 45 mT to about 300 mT, about 50 mT to about 200 mT, about 50 mT to about 100 mT, about 45 mT to about 100 mT, about 40 mT to about 100 mT, about 35 mT to about 100 mT, about 30 mT to about 100 mT, about 25 mT to about 100 mT, about 20 mT to about 100 mT, and about 15 mT to about 100 mT.

In accordance with various embodiments, the permanent magnet 230 can include a bore 235 in its center. In accordance with various embodiments, the permanent magnet 230 may not include a bore. In accordance with various embodiments, the bore 235 can have a diameter between 1 inch and 20 inches. In accordance with various embodiments, the bore 235 can have a diameter between 1 inch and 4 inches, between 4 inches and 8 inches, and between 10 inches and 20 inches. In accordance with various embodiments, the given field of view can be a spherical or cylindrical field of view, as shown in FIGS. 2A and 2B. In accordance with various embodiments, the spherical field of view can be between 2 inches and 20 inches in diameter. In accordance with various embodiments, the spherical field of view can have a diameter between 1 inch and 4 inches, between 4 inches and 8 inches, and between 10 inches and 20 inches. In accordance with various embodiments, the cylindrical field of view is approximately between 2 inches and 20 inches in length. In accordance with various embodiments, the cylindrical field of view can have a length between 1 inch and 4 inches, between 4 inches and 8 inches, and between 10 inches and 20 inches.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

Radio Frequency Transmit Coil

As discussed herein, and in accordance with various embodiments, the various systems, and various combinations of features that make up the various system embodiments, can also include a radio frequency transmit coil.

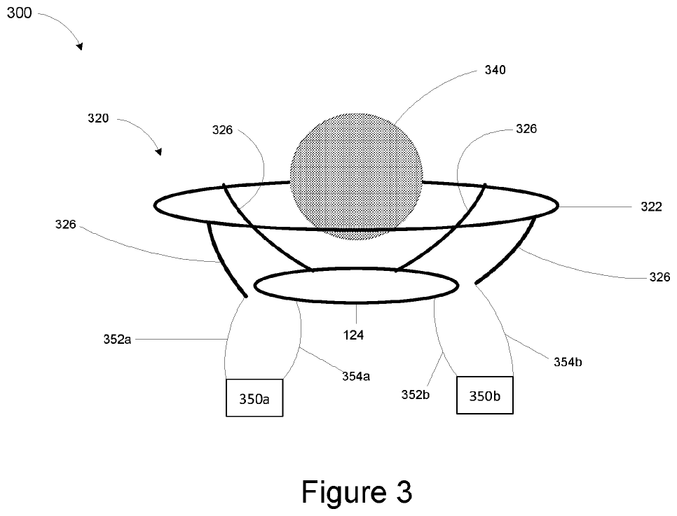

FIG. 3 is a schematic view of an implementation of a magnetic imaging apparatus 300, according to various embodiments. As shown in FIG. 3, the apparatus 300 includes a radio frequency transmit coil 320 that projects the RF power outwards away from the coil 320. The coil 320 has two rings 322 and 324 that are connected by one or more rungs 326. As shown in FIG. 3, the coil 320 is also connected to a power source 350a and/or a power source 350b (collectively referred to herein as “power source 350”). In accordance with various embodiments, power sources 350a and 350b can be configured for power input and/or signal input, and can generally be referred to as coil input. In accordance with various embodiments, the power source 350a and/or 350b are configured to provide contact via electrical contacts 352a and/or 352b (collectively referred to herein as “electrical contact 352”), and electrical contacts 354a and/or 354b (collectively referred to herein as “electrical contact 354b”) by attaching the electrical contacts 352 and 354 to one or more rungs 326. The coil 320 is configured to project a uniform RF field within a field of view 340. In accordance with various embodiments, the field of view 340 is a region of interest for magnetic resonance imaging (i.e., imaging region) where a patient resides. Since the patient resides in the field of view 340 away from the coil 320, the apparatus 300 is suitable for use in a single-sided magnetic resonance imaging system. In accordance with various embodiments, the coil 320 can be powered by two signals that are 90 degrees out of phase from each other, for example, via quadrature excitation.

In accordance with various embodiments, the coil 320 includes the ring 322 and the ring 324 that are positioned co-axially along the same axis but at a distance away from each other, as shown in FIG. 3. In accordance with various embodiments, the ring 322 and the ring 324 are separated by a distance ranging from about 0.1 m to about 10 m. In accordance with various embodiments, the ring 322 and the ring 324 are separated by a distance ranging from about 0.2 m to about 5 m, about 0.3 m to about 2 m, about 0.2 m to about 1 m, about 0.1 m to about 0.8 m, or about 0.1 m to about 1 m, inclusive of any separation distance therebetween. In accordance with various embodiments, the coil 320 includes the ring 322 and the ring 324 that are positioned non-co-axially but along the same direction and separated at a distance ranging from about 0.2 m to about 5 m. In accordance with various embodiments, the ring 322 and the ring 324 can also be tilted with respect to each other. In accordance with various embodiments, the tilt angle can be from 1 degree to 90 degrees, from 1 degree to 5 degrees, from 5 degrees to 10 degrees, from 10 degrees to 25 degrees, from 25 degrees to 45 degrees, and from 45 degrees to 90 degrees.

In accordance with various embodiments, the ring 322 and the ring 324 have the same diameter. In accordance with various embodiments, the ring 322 and the ring 324 have different diameters and the ring 322 has a larger diameter than the ring 324, as shown in FIG. 3. In accordance with various embodiments, the ring 322 and the ring 324 have different diameters and the ring 322 has a smaller diameter than the ring 324. In accordance with various embodiments, the ring 322 and the ring 324 of the coil 320 are configured to create the imaging region in the field of view 340 containing a uniform RF power profile within the field of view 340, a field of view that is not centered within the RF-TX coil and is instead projected outwards in space from the coil itself.

In accordance with various embodiments, the ring 322 has a diameter between about 10 μm and about 10 m. In accordance with various embodiments, the ring 322 has a diameter between about 0.001 m and about 9 m, between about 0.01 m and about 8 m, between about 0.03 m and about 6 m, between about 0.05 m and about 5 m, between about 0.1 m and about 3 m, between about 0.2 m and about 2 m, between about 0.3 m and about 1.5 m, between about 0.5 m and about 1 m, or between about 0.01 m and about 3 m, inclusive of any diameter therebetween.

In accordance with various embodiments, the ring 324 has a diameter between about 10 μm and about 10 m. In accordance with various embodiments, the ring 324 has a diameter between about 0.001 m and about 9 m, between about 0.01 m and about 8 m, between about 0.03 m and about 6 m, between about 0.05 m and about 5 m, between about 0.1 m and about 3 m, between about 0.2 m and about 2 m, between about 0.3 m and about 1.5 m, between about 0.5 m and about 1 m, or between about 0.01 m and about 3 m, inclusive of any diameter therebetween.

In accordance with various embodiments, the ring 322 and the ring 324 are connected by one or more rungs 326, as shown in FIG. 3. In accordance with various embodiments, the one or more rungs 326 are connected to the ring 322 and 324 so as to form a single electrical circuit loop (or single current loop). As shown in FIG. 3, for example, one end of the one or more rungs 326 is connected to the electrical contact 352 of the power source 350 and another end of the one or more rungs 326 be connected to the electrical contact 354 so that the coil 320 completes an electrical circuit.

In accordance with various embodiments, the ring 322 is a discontinuous ring and the electrical contact 352 and the electrical contact 354 can be electrically connected to two opposite ends of the ring 322 to form an electrical circuit powered by the power source 350. Similarly, in accordance with various embodiments, the ring 324 is a discontinuous ring and the electrical contact 352 and the electrical contact 354 can be electrically connected to two opposite ends of the ring 324 to form an electrical circuit powered by the power source 350.

In accordance with various embodiments, the rings 322 and 324 are not circular and can instead have a cross section that is elliptical, square, rectangular, or trapezoidal, or any shape or form having a closed loop. In accordance with various embodiments, the rings 322 and 324 may have cross sections that vary in two different axial planes with the primary axis being a circle and the secondary axis having a sinusoidal shape or some other geometric shape. In accordance with various embodiments, the coil 320 may include more than two rings 322 and 324, each connected by rungs that span and connect all the rings. In accordance with various embodiments, the coil 320 may include more than two rings 322 and 324, each connected by rungs that alternate connection points between rings. In accordance with various embodiments, the ring 322 may contain a physical aperture for access. In accordance with various embodiments, the ring 322 may be a solid sheet without a physical aperture.

In accordance with various embodiments, the coil 320 generates an electromagnetic field (also referred to herein as “magnetic field”) strength between about 1 μT and about 10 mT. In accordance with various embodiments, the coil 320 can generate a magnetic field strength between about 10 μT and about 5 mT, about 50 μT and about 1 mT, or about 100 μT and about 1 mT, inclusive of any magnetic field strength therebetween.

In accordance with various embodiments, the coil 320 generates an electromagnetic field that is pulsed at a radio frequency between about 1 kHz and about 2 GHz. In accordance with various embodiments, the coil 320 generates a magnetic field that is pulsed at a radio frequency between about 1 kHz and about 1 GHz, about 10 kHz and about 800 MHz, about 50 kHz and about 300 MHz, about 100 kHz and about 100 MHz, about 10 kHz and about 10 MHz, about 10 kHz and about 5 MHz, about 1 kHz and about 2 MHz, about 50 kHz and about 150 kHz, about 80 kHz and about 120 kHz, about 800 kHz and about 1.2 MHz, about 100 kHz and about 10 MHz, or about 1 MHz and about 5 MHz, inclusive of any frequencies therebetween.

In accordance with various embodiments, the coil 320 is oriented to partially surround the region of interest. In accordance with various embodiments, the ring 322, the ring 324, and the one or more rungs 326 are non-planar to each other. Said another way, the ring 322, the ring 324, and the one or more rungs 326 form a three-dimensional structure that surrounds the region of interest where a patient resides. In accordance with various embodiments, the ring 322 is closer to the region of interest than the ring 324, as shown in FIG. 3. In accordance with various embodiments, the region of interest has a size of about 0.1 m to about 1 m. In accordance with various embodiments, the region of interest is smaller than the diameter of the ring 322. In accordance with various embodiments, the region of interest is smaller than both the diameter of the ring 324 and the diameter of the ring 322, as shown in FIG. 3. In accordance with various embodiments, the region of interest has a size that is smaller than the diameter of the ring 322 and larger than the diameter of the ring 324.

In accordance with various embodiments, the ring 322, the ring 324, or the rungs 326 include the same material. In accordance with various embodiments, the ring 322, the ring 324, or the rungs 326 include different materials. In accordance with various embodiments, the ring 322, the ring 324, or the rungs 326 include hollow tubes or solid tubes. In accordance with various embodiments, the hollow tubes or solid tubes can be configured for air or fluid cooling. In accordance with various embodiments, each of the ring 322 or the ring 324 or the rungs 326 includes one or more electrically conductive windings. In accordance with various embodiments, the windings include litz wires or any electrical conducting wires. These additional windings could be used to improve performance by lowering the resistance of the windings at the desired frequency. In accordance with various embodiments, the ring 322, the ring 324, or the rungs 326 include copper, aluminum, silver, silver paste, or any high electrical conducting material, including metal, alloys or superconducting metal, alloys or non-metal. In accordance with various embodiments, the ring 322, the ring 324, or the rungs 326 may include metamaterials.

In accordance with various embodiments, the ring 322, the ring 324, or the rungs 326 may contain separate electrically non-conductive thermal control channels designed to maintain the temperature of the structure to a specified setting. In accordance with various embodiments, the thermal control channels can be made from electrically conductive materials and integrated as to carry the electrical current.

In accordance with various embodiments, the coil 320 includes one or more electronic components for tuning the magnetic field. The one or more electronic components can include a varactor, a PIN diode, a capacitor, or a switch, including a micro-electro-mechanical system (MEMS) switch, a solid state relay, or a mechanical relay. In accordance with various embodiments, the coil can be configured to include any of the one or more electronic components along the electrical circuit. In accordance with various embodiments, the one or more components can include mu metals, dielectrics, magnetic, or metallic components not actively conducting electricity and can tune the coil. In accordance with various embodiments, the one or more electronic components used for tuning includes at least one of dielectrics, conductive metals, metamaterials, or magnetic metals. In accordance with various embodiments, tuning the electromagnetic field includes changing the current or by changing physical locations of the one or more electronic components. In accordance with various embodiments, the coil is cryogenically cooled to reduce resistance and improve efficiency. In accordance with various embodiments, the first ring and the second ring comprise a plurality of windings or litz wires.

In accordance with various embodiments, the coil 320 is configured for a magnetic resonance imaging system that has a magnetic field gradient across the field of view. The field gradient allows for imaging slices of the field of view without using an additional electromagnetic gradient. As disclosed herein, the coil can be configured to generate a large bandwidth by combining multiple center frequencies, each with their own bandwidth. By superimposing these multiple center frequencies with their respective bandwidths, the coil 320 can effectively generate a large bandwidth over a desired frequency range between about 1 kHz and about 2 GHz. In accordance with various embodiments, the coil 320 generates a magnetic field that is pulsed at a radio frequency between about 10 kHz and about 800 MHz, about 50 kHz and about 300 MHz, about 100 kHz and about 100 MHz, about 10 kHz and about 10 MHz, about 10 kHz and about 5 MHz, about 1 kHz and about 2 MHz, about 50 kHz and about 150 kHz, about 80 kHz and about 120 kHz, about 800 kHz and about 1.2 MHz, about 100 kHz and about 10 MHz, or about 1 MHz and about 5 MHz, inclusive of any frequencies therebetween.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

Gradient Coil Set

As discussed herein, and in accordance with various embodiments, the various systems, and various combinations of features that make up the various system embodiments, can also include a gradient coil set.

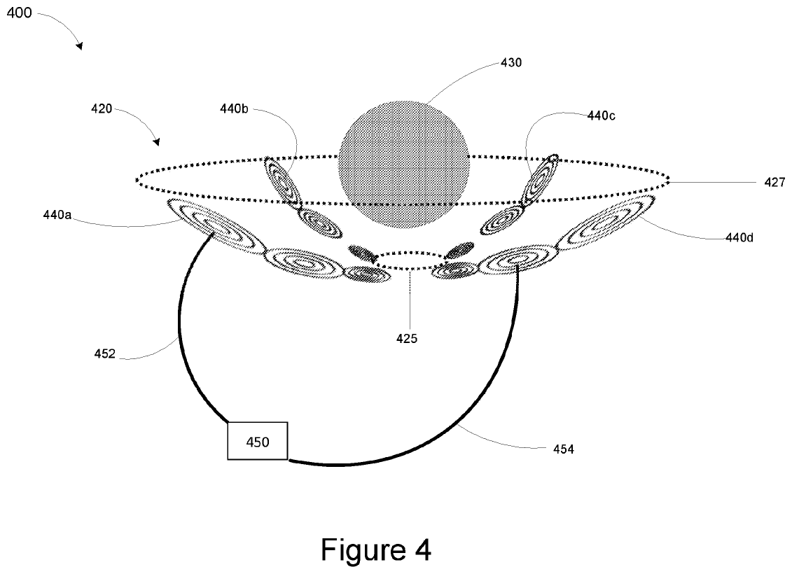

FIG. 4 is a schematic view of an implementation of a magnetic imaging apparatus 400, according to various embodiments. As shown in FIG. 4, the apparatus 400 includes a gradient coil set 420 (also referred to herein as single-sided gradient coil set 420) that is configured to project a gradient magnetic field outwards away from the coil set 420 and within a field of view 430. In accordance with various embodiments, the field of view 430 is a region of interest for magnetic resonance imaging (i.e., imaging region) where a patient resides. Since the patient resides in the field of view 430 away from the coil set 420, the apparatus 400 is suitable for use in a single-sided MRI system.

As shown in the figure, the coil set 420 includes variously sized spiral coils in various sets of spiral coils 440a, 440b, 440c, and 440d (collectively referred to as “spiral coils 440”). Each set of the spiral coils 440 include at least one spiral coil and FIG. 4 is shown to include 3 spiral coils. In accordance with various embodiments, each spiral coil in the spiral coils 440 has an electrical contact at its center and an electrical contact output on the outer edge of the spiral coil so as to form a single running loop of electrically conducting material spiraling out from the center to the outer edge, or vice versa. In accordance with various embodiments, each spiral coil in the spiral coils 440 has a first electrical contact at a first position of the spiral coil and a second electrical contact at a second position the spiral coil so as to form a single running loop of electrically conducting material from the first position to the second position, or vice versa.

As shown in FIG. 4, the coil set 420 also includes an aperture 425 at its center where the spiral coils 440 are disposed around the aperture 425. The aperture 425 itself does not contain any coil material within it for generating magnetic material. The coil set 420 also includes an opening 427 on the outer edge of the coil set 420 to which the spiral coils 440 can be disposed. Said another way, the aperture 425 and the opening 427 define the boundaries of the coil set 420 within which the spiral coils 440 can be disposed. In accordance with various embodiments, the coil set 420 forms a bowl shape with a hole in the center.

In accordance with various embodiments, the spiral coils 440 form across the aperture 425. For example, the spiral coils 440a are disposed across from the spiral coils 440c with respect to the aperture 425. Similarly, the spiral coils 440b are disposed across from the spiral coils 440d with respect to the aperture 425. In accordance with various embodiments, the spiral coils 440 in the coil set 420 shown in FIG. 4 are configured to create spatial encoding in the magnetic gradient field within the field of view 430.

As shown in FIG. 4, the coil set 420 is also connected to a power source 450 via electrical contacts 452 and 454 by attaching the electrical contacts 452 and 454 to one or more of the spiral coils 440. In accordance with various embodiments, the electrical contact 452 is connected to one of the spiral coils 440, which is then connected to other spiral coils 440 in series and/or in parallel, and one other spiral coil 440 is then connected to the electrical contact 454 so as to form an electrical current loop. In accordance with various embodiments, the spiral coils 440 are all electrically connected in series. In accordance with various embodiments, the spiral coils 440 are all electrically connected in parallel. In accordance with various embodiments, some of the spiral coils 440 are electrically connected in series while other spiral coils 440 are electrically connected in parallel. In accordance with various embodiments, the spiral coils 440a are electrically connected in series while the spiral coils 440b are electrically connected in parallel. In accordance with various embodiments, the spiral coils 440c are electrically connected in series while the spiral coils 440d are electrically connected in parallel. The electrical connections between each spiral coil in the spiral coils 440 or each set of spiral coils 440 can be configured as needed to generate the magnetic field in the field of view 430.

In accordance with various embodiments, the coil set 420 includes the spiral coils 440 spread out as shown in FIG. 4. In accordance with various embodiments, each of the sets of spiral coils 440a, 440b, 440c, and 440d are configured in a line from the aperture 425 to the opening 427 so that each set of spiral coils is set apart from another by an angle of 90°. In accordance with various embodiments, 440a and 440b are set at 45° from one another, and 440c and 440d are set at 45° from one another, while 440c is set 135° on the other side of 440b and 440d is set 135° on the other side of 440a. In essence, any of the sets of spiral coils 440 can be configured in any arrangement for any number “n” of sets of spiral coils 440.

In accordance with various embodiments, the spiral coils 440 have the same diameter. In accordance with various embodiments, each of the sets of spiral coils 440a, 440b, 440c, and 440d have the same diameter. In accordance with various embodiments, the spiral coils 440 have different diameters. In accordance with various embodiments, each of the sets of spiral coils 440a, 440b, 440c, and 440d have different diameters. In accordance with various embodiments, the spiral coils in each of the sets of spiral coils 440a, 440b, 440c, and 440d have different diameters. In accordance with various embodiments, 440a and 440b have the same first diameter and 440c and 440d have the same second diameter, but the first diameter and the second diameter are not the same.

In accordance with various embodiments, each spiral coil in the spiral coils 440 has a diameter between about 10 μm and about 10 m. In accordance with various embodiments, each spiral coil in the spiral coils 440 has a diameter between about 0.001 m and about 9 m, between about 0.005 m and about 8 m, between about 0.01 m and about 6 m, between about 0.05 m and about 5 m, between about 0.1 m and about 3 m, between about 0.2 m and about 2 m, between about 0.3 m and about 1.5 m, between about 0.5 m and about 1 m, or between about 0.01 m and about 3 m, inclusive of any diameter therebetween.

In accordance with various embodiments, the spiral coils 440 are connected to form a single electrical circuit loop (or single current loop). As shown in FIG. 4, for example, one spiral coil in the spiral coils 440 is connected to the electrical contact 452 of the power source 450 and another spiral coil be connected to the electrical contact 454 so that the spiral coils 440 completes an electrical circuit.

In accordance with various embodiments, the coil set 420 generates an electromagnetic field strength (also referred to herein as “electromagnetic field gradient” or “gradient magnetic field”) between about 1 μT and about 10 T. In accordance with various embodiments, the coil set 420 can generate an electromagnetic field strength between about 100 μT and about 1 T, about 1 mT and about 500 mT, or about 10 mT and about 100 mT, inclusive of any magnetic field strength therebetween. In accordance with various embodiments, the coil set 420 can generate an electromagnetic field strength greater than about 1 μT, about 10 μT, about 100 μT, about 1 mT, about 5 mT, about 10 mT, about 20 mT, about 50 mT, about 100 mT, or about 500 mT.

In accordance with various embodiments, the coil set 420 generates an electromagnetic field that is pulsed at a rate with a rise-time less than about 100 μs. In accordance with various embodiments, the coil set 420 generates an electromagnetic field that is pulsed at a rate with a rise-time less than about 1 μs, about 5 μs, about 10 μs, about 20 μs, about 30 μs, about 40 μs, about 50 μs, about 100 μs, about 200 μs, about 500 μs, about 1 ms, about 2 ms, about 5 ms, or about 10 ms.

In accordance with various embodiments, the coil set 420 is oriented to partially surround the region of interest in the field of view 430. In accordance with various embodiments, the spiral coils 440 are non-planar to each other. In accordance with various embodiments, the sets of spiral coils 440a, 440b, 440c, and 440d are non-planar to each other. Said another way, the spiral coils 440 and each of the sets of spiral coils 440a, 440b, 440c, and 440d form a three-dimensional structure that surrounds the region of interest in the field of view 430 where a patient resides.

In accordance with various embodiments, the spiral coils 440 include the same material. In accordance with various embodiments, the spiral coils 440 include different materials. In accordance with various embodiments, the spiral coils in set 440a include the same first material, the spiral coils in set 440b include the same second material, the spiral coils in set 440c include the same third material, the spiral coils in set 440d include the same fourth material, but the first, second, third and fourth materials are different materials. In accordance with various embodiments, the first and second materials are the same material, but that same material is different from the third and fourth materials, which are the same. In essence, any of the spiral coils 440 can be of the same material or different materials depending on the configuration of the coil set 420.

In accordance with various embodiments, the spiral coils 440 include hollow tubes or solid tubes. In accordance with various embodiments, the spiral coils 440 include one or more windings. In accordance with various embodiments, the windings include litz wires or any electrical conducting wires. In accordance with various embodiments, the spiral coils 440 include copper, aluminum, silver, silver paste, or any high electrical conducting material, including metal, alloys or superconducting metal, alloys or non-metal. In accordance with various embodiments, the spiral coils 440 include metamaterials.

In accordance with various embodiments, the coil set 420 includes one or more electronic components for tuning the magnetic field. The one or more electronic components can include a PIN diode, a mechanical relay, a solid state relay, or a switch, including a micro-electro-mechanical system (MEMS) switch. In accordance with various embodiments, the coil can be configured to include any of the one or more electronic components along the electrical circuit. In accordance with various embodiments, the one or more components can include mu metals, dielectrics, magnetic, or metallic components not actively conducting electricity and can tune the coil. In accordance with various embodiments, the one or more electronic components used for tuning includes at least one of conductive metals, metamaterials, or magnetic metals. In accordance with various embodiments, tuning the electromagnetic field includes changing the current or by changing physical locations of the one or more electronic components. In some implementations, the coil is cryogenically cooled to reduce resistance and improve efficiency.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

Electromagnet

As discussed herein, and in accordance with various embodiments, the various systems, and various combinations of features that make up the various system embodiments, can also include an electromagnet.

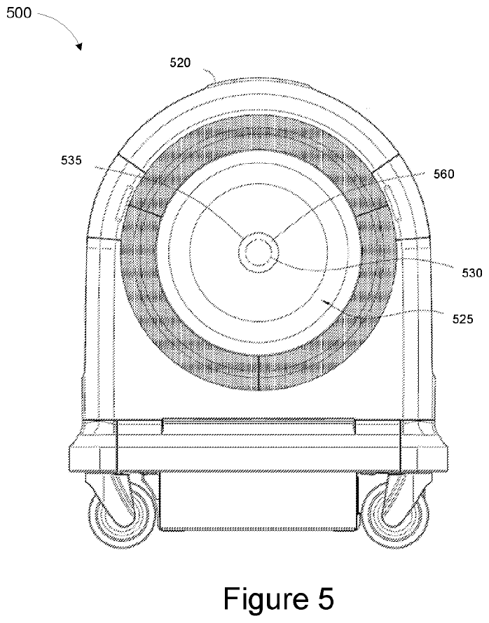

FIG. 5 is a schematic front view of a magnetic resonance imaging system 500, according to various embodiments. In accordance with various embodiments, the system 500 can be any magnetic resonance imaging system, including for example, a single-sided magnetic resonance imaging system that comprises a magnetic resonance imaging scanner or a magnetic resonance imaging spectrometer, as disclosed herein.

As shown in FIG. 5, the system 500 includes a housing 520 that can house various components, including, for example but not limited to, magnets, electromagnets, coils for producing radio frequency fields, various electronic components, for example but not limited to, for controlling, powering, and/or monitoring of the system 500. In accordance with various embodiments, the housing 520 can house, for example, the permanent magnet 230, the radio frequency transmit coil 240, and/or the gradient coil set 250 within the housing 520. In accordance with various embodiments, the system 500 also includes a bore 535 in its center. As shown in FIG. 5, the housing 520 also includes a front surface 525 of the system 500. In accordance with various embodiments, the front surface 525 can be curved, flat, concave, convex, or otherwise have a straight or curvilinear surface. In accordance with various embodiments, the magnetic resonance imaging system 500 can be configured to provide a region of interest in field of view 530.

As shown in FIG. 5, the system 500 includes an electromagnet 560 disposed proximate to the front surface 525 of the system 500. In accordance with various embodiments, the electromagnet 560 is disposed proximate to the center of the front surface 525 on the front side of the system 500. In accordance with various embodiments, the electromagnet 560 can be a solenoid coil configured to create a field that either adds or subtracts from the magnetic field, for example, of the permanent magnet 230. In accordance with various embodiments, this field can create a prepolarizing field for enhancing the signal or contrast from the nuclear magnetic resonance.

As shown in FIG. 5, the given field of view 530 resides at the center of the front surface 525 of the system 500. In accordance with various embodiments, the electromagnet 560 is disposed within the given field of view 530. In accordance with various embodiments, the electromagnet 560 is disposed concentrically with the given field of view 530. In accordance with various embodiments, the electromagnet 560 can be inserted in the bore 535. In accordance with various embodiments, the electromagnet 560 can be placed proximate to the bore 535. For example, the electromagnet 560 can be placed in front, back or middle of the bore 535. In accordance with various embodiments, the electromagnet 560 can be placed proximate to, or at the entrance of the bore 535.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

Radio Frequency Receive Coil

As discussed herein, and in accordance with various embodiments, the various systems, and various combinations of features that make up the various system embodiments, can also include a radio frequency receive coil.

Typical MR systems create a uniform field within the imaging region. This uniform field then generates a narrow band of magnetic resonance frequencies that can then be captured by a receive coil, amplified, and digitized by a spectrometer. Since frequencies are within a narrow well-defined bandwidth, hardware architecture is focused on creating a statically tuned RF-RX coil with an optimal coil quality factor. Many variations in coil architectures have been created that explore large single volume coils, coil arrays, parallelized coil arrays, or body specific coil arrays. However, these structures are all predicated on imaging a specific frequency close to the region of interest at high field strengths and small as possible within a magnetic bore.

In accordance with various embodiments, an MRI system is provided that can include a unique imaging region that can be offset from the face of a magnet and therefore unobstructed as compared to traditional scanners. In addition, this form factor can have a built-in magnetic field gradient that creates a range of field values over the region of interest. Lastly, this system can operate at a lower magnetic field strength as compared to typical MRI systems allowing for a relaxation on the RX coil design constraints and allowing for additional mechanisms like robotics to be used with the MRI.

The unique architecture of the main magnetic field of the MRI system, in accordance with various embodiments, can create a different set of optimization constraints. Because the imaging volume now extends over a broader range of magnetic resonance frequencies, the hardware can be configured to be sensitive to and capture the specific frequencies that are generated across the field of view. This frequency spread is usually much larger than a single receive coil tuned to a single frequency can be sensitive to. In addition, because the field strength can be much lower than traditional systems, and because signal intensity can be proportional to the field strength, it is generally considered to be beneficial to maximize the signal to noise ratio of the receive coil network. Methods are therefore provided, in accordance with various embodiments, to acquire the full range of frequencies that are generated within the field of view without loss of sensitivity.

In accordance with various embodiments, several methods are provided that can enable imaging within the MRI system. These methods can include combining 1) a variable tuned RF-RX coil; 2) a RF-RX coil array with elements tuned to frequencies that are dependent upon the spatial inhomogeneity of the magnetic field; 3) a ultralow-noise pre-amplifier design; and 4) an RF-RX array with multiple receive coils designed to optimize the signal from a defined and limited field of view for a specific body part. These methods can be combined in any combination as needed.

In accordance with various embodiments, a variable tuned RF-RX coil can comprise one or more electronic components for tuning the electromagnetic receive field. In accordance with various embodiments, the one or more electronic components can include at least one of a varactor, a PIN diode, a capacitor, an inductor, a MEMS switch, a solid state relay, or a mechanical relay. In accordance with various embodiments, the one or more electronic components used for tuning can include at least one of dielectrics, capacitors, inductors, conductive metals, metamaterials, or magnetic metals. In accordance with various embodiments, tuning the electromagnetic receive field includes changing the current or by changing physical locations of the one or more electronic components. In accordance with various embodiments, the coil is cryogenically cooled to reduce resistance and improve efficiency.

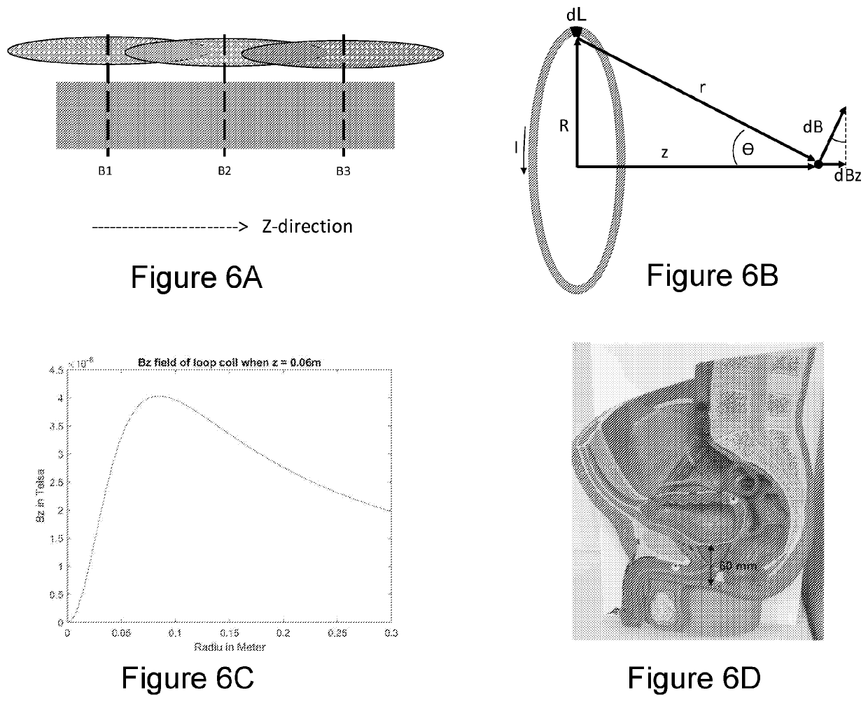

In accordance with various embodiments, the RF-RX array can be comprised of individual coil elements that are each tuned to a variety of frequencies. The appropriate frequency can be chosen, for example, to match the frequency of the magnetic field located at the specific spatial location where the specific coil is located. Because the magnetic field can vary as a function of space, as shown in FIG. 6A, the field and frequency of the coil can be adjusted to approximately match the spatial location. Here the coils can be designed to image the field locations B1, B2, and B3, which are physically separated along a single axis.

For this low field system, in accordance with various embodiments, a low-noise preamplifier can be designed and configured to leverage the low signal environment of the MRI system. This low noise amplifier can be configured to utilize components that do not generate significant electronic and voltage noise at the desired frequencies (for example, <3 MHz and >2 MHz). Typical junction field effect transistor designs (J-FET) generally do not have the appropriate noise characteristics at this frequency and can create high frequency instabilities at the GHz range that can bleed into, although several decades of dB lower, into the measured frequency range. Since the gain of the system can preferably be, for example, >80 dB overall, any small instabilities or intrinsic electrical noise can be amplified and degrade signal integrity.

Referring to FIG. 6B, RF-RX coils can be designed to image specific limited field of views based upon the target anatomy. The prostate, for example, is about 60 millimeters deep within the human body (see FIG. 6D), so to design a RX coil for prostate imaging, the coil should be configured to enable imaging 60 mm deep inside human body. According to Biot-Savart law, the magnetic field of a loop coil can be calculated by the following equation,

$$B z = \frac{{μ}_{0}}{4 π} * \frac{2 π * {R}^{2} * I}{{( {z}^{2} + {R}^{2} )}^{\frac{3}{2}}}$$

where μ0=4π*10-7H/m is the vacuum permeability, R is the radius of the loop coil, z is distance along the center line of the coil from its center, and I is the current on the coil (see FIG. 6B). Assuming I=1 Ampere, with the goal of locating a figure of magnetic field (Bz) at z=60 mm, the maximum position is when R is 85 mm according to the chart shown in FIG. 6C.

Based upon the geometrical constraints of the body, the loop coil can be set up at the space between the human legs upon the torso. As such, it is extremely difficult, if not impossible, to fit a 170-mm diameter coil there. According to FIG. 6C, the Bz field value is proportional to the radius of the loop when R is less than 85 mm. As such, it is advantageous that the coil be as large as it can be. For example, the largest loop coil that can be placed between people is about 10 mm large.

As the size of the coil is limited by the space between legs, the magnetic field of a 10-mm diameter coil is generally not capable of reaching the depth of prostate. Therefore, single coil may not be enough for prostate imaging thus, in this case, multiple coils could prove beneficial in getting signal from different directions. In various embodiments of the MRI system, the magnetic field is provided in the z-direction and RF coils are sensitive to x- and y-direction. In this example case, a loop coil in x-y plane would not collect RF signal from a human since it is sensitive to z-direction, while a butterfly coil can be used in this case. Then based on the location and orientation, RF coil could be a loop coil or butterfly coil. In addition, a coil can be placed in under the body and there is no limitation for its size.

As for the needs of multiple RX coils, in various embodiments, decoupling between them can prove beneficial for various embodiments of an MRI system RX coil array. In those cases, each coil can be de-coupled with the other coils, and the decoupling techniques can include, for example, 1) geometry decoupling, 2) capacitive/inductive decoupling, and 3) low-/high impedance pre-amplifier coupling.

The MRI system, in accordance with various embodiments, can have a variant magnetic field from the magnet, and its strength can vary linearly along the z direction. The RX coils can be located in different positions in z-direction, and each coil can be tuned to different frequencies, which can depend on the location of the coils in the system.

Based upon the simplicity of single coil loops, these coils can be constructed from simple conductive traces that can be pre-tuned to a desired frequency and printed, for example, on a disposable substrate. This cheaply fabricated technology can allow a clinician to place the RX coil (or coil array) upon the body at the region of interest for a given procedure and dispose of the coil afterwards. For example, and in accordance with various embodiments, the RX coils can be surface coils, which can be affixed to, e.g., worn or taped to, a patient's body. For other body parts, e.g. an ankle or a wrist, the surface coil might be a single-loop configuration, figure-8 configuration, or butterfly coil configuration wrapped around the region of interest. For regions that require significant penetration depth, e.g. the torso or knee, the coil might consist of a Helmholtz coil pair. The main restriction to the receive coil is similar to other MRI systems: the coil must be sensitive to a plane that is orthogonal to the main magnetic field, B0, axis.

In accordance with various embodiments, the coils might be inductively coupled to another loop that is electrically connected to the receive preamplifier. This design would allow for easier and unobstructed access of the receive coils.

In accordance with various embodiments, the size of coils can be limited by the structure of human body. For example, the coils' size should be positioned and configured to fit in the space between human legs when imaging the prostate.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

Programmable Logic Controller

As discussed herein, and in accordance with various embodiments, the various systems, and various combinations of features that make up the various system embodiments, can also include a programmable logic controller (PLC). PLCs are industrial digital computers which can be designed to operate reliably in harsh usage environments and conditions. PLCs can be designed to handle these types of conditions and environments, not just in the external housing, but in the internal components and cooling arrangements as well. As such, PLCs can be adapted for the control of manufacturing processes, such as assembly lines, or robotic devices, or any activity that requires high reliability control and ease of programming and process fault diagnosis.

In accordance with various embodiments, the system can contain a PLC that can control the system in pseudo real-time. This controller can manage the power cycling and enabling of the gradient amplifier system, the radio frequency transmission system, the frequency tuning system, and sends a keep alive signal (e.g., a message sent by one device to another to check that the link between the two is operating, or to prevent the link from being broken) to the system watchdog. The system watchdog can continually look for a strobe signal supplied by the computer system. If the computer threads stall, a strobe is missed that can trigger the watchdog to enter a fault condition. If the watchdog enters a fault condition, the watchdog can operated to depower the system.

The PLC can generally handle low level logic functions on incoming and outgoing signals into system. This system can monitor the subsystem health and control when subsystems needed to be powered or enabled. The PLC can be designed in different ways. One design example includes a PLC with one main motherboard with four expansion boards. Due to the speed of the microcontroller on the PLC, subsystems can be managed in pseudo real-time, while real-time applications can be handled by the computer or spectrometer on the system.

The PLC can serve many functional responsibilities including, for example, powering on/off the gradient amplifiers (discussed in greater detail herein) and the RF amplifier (discussed in greater detail herein), enabling/disabling the gradient amplifiers and the RF amplifier, setting the digital and analog voltages for the RF coil tuning, and strobing the system watchdog.

As discussed above, it should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

Robot

As discussed herein, and in accordance with various embodiments, the various systems, and various combinations of features that make up the various system embodiments, can also include a robot.

In some medical procedures, such as a prostate biopsy, it is typical for the patient to endure a lengthy procedure in an uncomfortable prone position, which often includes remaining motionless in one specific body position during the entire procedure. In such long procedures, if a metallic ferromagnetic needle is used for the biopsy with guidance from an MRI system, the needle may experience attraction force from the strong magnets of the MRI system, and thus may cause it to deviate from its path during the length of the procedure. Even in the case of using a non-magnetic needle, the local field distortions can cause distortions in the magnetic resonance images, and therefore, the image quality surrounding the needle may result in a poor quality. To avoid such distortions, pneumatic robots with complex compressed air mechanism have been designed to work in conjunction with conventional MRI systems. Even then, access to target anatomy remains challenging due to the form factor of currently available MRI systems.

The various embodiments presented herein include improved MRI systems that are configured to use for guiding in medical procedures, including, for example, robot-assisted, invasive medical procedures. The technologies, methods and apparatuses disclosed herein relate to a guided robotic system using magnetic resonance imaging as a guidance to automatically guide a robot (generally referred to herein as “a robotic system”) in medical procedures. In accordance with various embodiments, the disclosed technologies combine a robotic system with magnetic resonance imaging as guidance. In accordance with various embodiments, the robotic system disclosed herein is combined with other suitable imaging techniques, for example, ultrasound, x-ray, laser, or any other suitable diagnostic or imaging methodologies.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

Spectrometer

As discussed herein, and in accordance with various embodiments, the various systems, and various combinations of features that make up the various system embodiments, can also include a spectrometer.

A spectrometer can operate to control all real-time signaling used to generate images. It creates the RF transmission (RF-TX) waveform, gradient waveforms, frequency tuning trigger waveform, and blanking bit waveforms. These waveforms are then synchronized with the RF receiver (RF-RX) signals. This system can generate frequency swept RF-TX pulses and phase cycled RF-TX pulses. The swept RF-TX pulses allow for an inhomogeneous B1+field (RF-TX field) to excite a sample volume more effectively and efficiently. It can also digitize multiple RF-RX channels with the current configuration set to four receiver channels. However, this system architecture allows for an easy system scale-up to increase the number of transmit and receive channels to a maximum of 32 transmit channels and 16 receive channels without having to change the underlying hardware or software architecture.

The spectrometer can serve many functional responsibilities including, for example, generating and synchronizing the RF-TX (discussed in greater detail herein) waveforms, X-gradient waveforms, Y-gradient waveforms, blanking bit waveforms, frequency tuning trigger waveform and RF-RX windows, and digitizing and signal processing the RF-RX data using, for example, quadrature demodulation followed by a finite impulse response filter decimation such as, for example, a cascade integrating comb (CIC) filter decimation.

The spectrometer can be designed in different ways. One design example includes a spectrometer with three main components: 1) a first software design radio (SDR 1) operating with Basic RF-TX daughter cards and Basic RF-RX daughter cards; 2) a second software design radio (SDR 2) operating with LFRF TX daughter cards and Basic RF-RX daughter cards; and 3) a clock distribution module (octoclock) that can synchronize the two devices.

SDRs are the real-time communication device between the transmitted signals and received MRI signals. They can communicate over 10 Gbit optical fiber to the computer using a Small Form-factor Pluggable Plus transceiver (SFP+) communication protocol. This communication speed can allows the waveforms to be generated with high fidelity and high reliability.

Each SDR can include a motherboard with an integrated field-programmable gate array (FPGA), digital to analog converters, analog to digital converters, and four module slots for integrating different daughtercards. Each of these daughtercards can function to change the frequency response of the associated TX or RX channel. In accordance with various embodiments, the system can utilizes many variations daughtercards including, for example, a Basic RF version, and a low frequency (LF) RF version. The Basic RF daughtercards can be used for generating and measuring RF signals. The LF RF version can be used for generating gradient, trigger and blanking bit signals.

The octoclock can be used to synchronize a multi-channel SDR system to a common timing source while providing high-accuracy time and frequency reference distribution. It can do so, for example, with 8-way time and frequency distribution (1 PPS and 10 MHz). An example of an octoclock is the Ettus Octoclock CDA, which can distribute a common clock to up to eight SDRs to ensure phase coherency between the two or more SDR sources.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

RF AMP/Gradient AMP

As discussed herein, and in accordance with various embodiments, the various systems, and various combinations of features that make up the various system embodiments, can also include a radio frequency amplifier (RF amplifier) and a gradient amplifier.

A RF amplifier is a type of electronic amplifier that can converts a low-power radio-frequency signal into a higher power signal. In operation, the RF amplifier can accept signals at low amplitudes and provide, for example, up to 60 dB of gain with a flat frequency response. This amplifier can accept three phase AC input voltage and can have a 10% max duty cycle. The amplifier can be gated by a 5V digital signal so that unwanted noise is not generated when the MRI is receiving signal.

In operation, a gradient amplifier can increase the energy of the signal before it reaches the gradient coils such that the field strength can be intense enough to produce the variations in the main magnetic field for localization of the later received signal. The gradient amplifier can have two active amplification channels that can be controlled independently. Each channel can send out current to either the X or Y channel respectively. The third axis of spatial encoding is generally handled by a permanent gradient in the main magnetic field (B0). With varying combinations of pulse sequences, the signal can be localized in three dimensions and reconstructed to create an object.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

Display/GUI

As discussed herein, and in accordance with various embodiments, the various systems, and various combinations of features that make up the various system embodiments, can also include a display in the form of, for example, a graphical user interface (GUI). In accordance with various embodiments, the GUI can take any contemplated form necessary to convey the information necessary to run magnetic resonance imaging procedures.

Further, it should be appreciated that the display may be embodied in any of a number of other forms, such as, for example, a rack-mounted computer, mainframe, supercomputer, server, client, a desktop computer, a laptop computer, a tablet computer, hand-held computing device (e.g., PDA, cell phone, smart phone, palmtop, etc.), cluster grid, netbook, embedded systems, or any other type of special or general purpose display device as may be desirable or appropriate for a given application or environment.

The GUI is a system of interactive visual components for computer software. A GUI can display objects that convey information, and represent actions that can be taken by the user. The objects change color, size, or visibility when the user interacts with them. GUI objects include, for example, icons, cursors, and buttons. These graphical elements are sometimes enhanced with sounds, or visual effects like transparency and drop shadows.

A user can interact with a GUI using an input device, which can include, for example, alphanumeric and other keys, mouse, a trackball or cursor direction keys for communicating direction information and command selections to a processor and for controlling cursor movement on the display. An input device may also be the display configured with touchscreen input capabilities. This input device typically has two degrees of freedom in two axes, a first axis (i.e., x) and a second axis (i.e., y), that allows the device to specify positions in a plane. However, it should be understood that input devices allowing for 3 dimensional (x, y and z) cursor movement are also contemplated herein.

In accordance with various embodiments, the touchscreen, or touchscreen monitor, can serves as the primary human interface device that allows a user to interact with the MRI. The screen can have a projected capacitive touch sensitive display with an interactive virtual keyboard. The touchscreen can have several functions including, for example, displaying the graphical user interface (GUI) to the user, relaying user input to the system's computer, and starting or stopping a scan.

In accordance with various embodiments, GUI views can be typically screens displayed (Qt widgets) to the user with appropriate buttons, edit fields, labels, images, etc. These screens can be constructed using a designer tool such as, for example, the Qt designer tool, to control placement of widgets, their alignment, fonts, colors, etc. A user interface (UI) sub controller can possess modules configured to control the behavior (display and responses) of the respective view modules.

Several application utilities (App Util) modules can performs specific functions. For example, S3 modules can handle data communication between the system and, for example, Amazon Web Services (AWS). Event Filters can be present to ensure valid characters are displayed on screen when user inputs are required. Dialog messages can be used to show various status, progress messages or require user prompts. Moreover, a system controller module can be utilized to handle coordination between the sub controller modules, and key data processing blocks in the system, the pulse sequence generator, pulse interpreter, spectrometer and reconstruction.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

Processing Module

As discussed herein, and in accordance with various embodiments, the various workflows or methods, and various combinations of steps that make up the various workflow or method embodiments, can also include a processing module.

In accordance with various embodiments, a processing module serves many functions. For example, a processing module can generally operate to receive signal data acquired during the scan, process the data, and reconstruct those signals to produce an image that can be viewed (for example, via a touchscreen monitor that displays a GUI to the user), analyzed and annotated by system users. Generally, to create an image, an NMR signal must be localized in three-dimensional space. Magnetic gradient coils localize the signal and are operated before or during the RF acquisition. By prescribing a RF and gradient coil application sequence, called a pulse sequence, the signals acquired correspond to a specific magnetic field and RF field arrangement. Using mathematical operators and image reconstruction techniques, arrays of these acquired signals can be reconstructed into an image. Usually these images are generated from simple linear combinations of magnetic field gradients. In accordance with various embodiments, the system can operate to reconstruct the acquired signals from a-priori knowledge of, for example, the gradient fields, RF fields, and pulse sequences.

In accordance with various embodiments, the processing module can also operate to compensate for patient motion during a scan procedure. Motion (e.g., beating heart, breathing lungs, bulk patient movement) is one of the most common sources of artifacts in MRI, with such artifacts affecting image quality by leading to misinterpretations in the images and a subsequent loss in diagnostic quality. Therefore, motion compensation protocols can help address these issues at minimal cost in time, spatial resolution, temporal resolution, and signal-to-noise ratio.

In accordance with various embodiments, the processing module might include artificial intelligence machine learning modules designed to denoise the signal and improve the image signal-to-noise ratio.

In accordance with various embodiments, the processing module can also operate to assist clinicians in planning a path for subsequent patient intervention procedures, such as biopsy. In accordance with various embodiments, a robot can be provided as part of the system to perform the intervention procedure. The processing module can communicate instructions to the robot, based on image analysis, to properly access, for example, the appropriate region of the body requiring a biopsy.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described below. It should further be noted that exemplary description of specific features are used, largely for informational purposes, and not in any way to limit the design, subfeature, and functionality of the specifically described feature.

In accordance with various embodiments, the various systems, and various combinations of features that make up the various system components and embodiments of the disclosed magnetic resonance imaging system are disclosed herein.

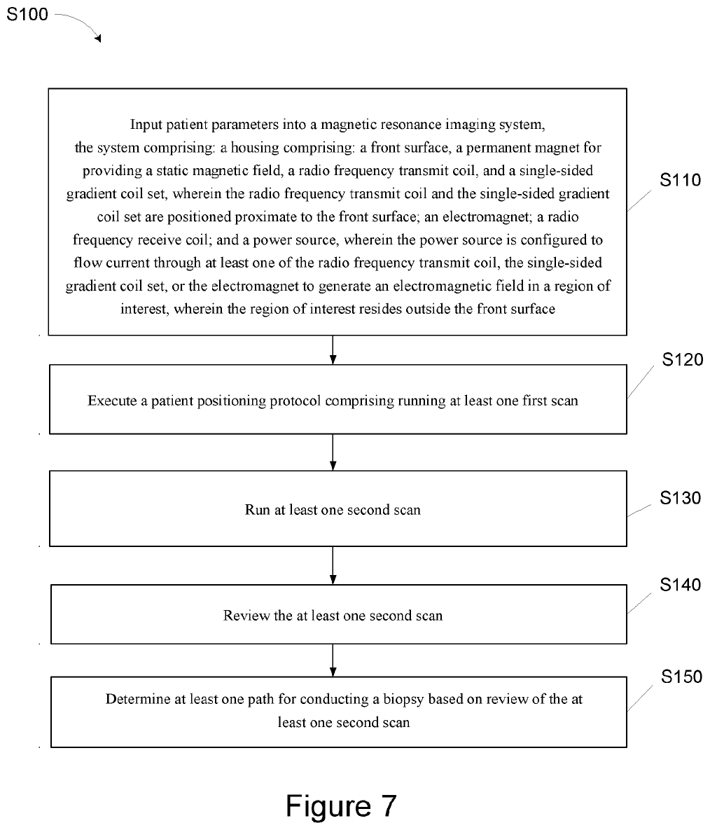

FIG. 7 is a flowchart for a method S100 of performing magnetic resonance imaging, according to various embodiments. In accordance with various embodiments, the method S100 includes inputting patient parameters into a magnetic resonance imaging system at step S110. In accordance with various embodiments, the system includes a housing having a front surface, a permanent magnet for providing a static magnetic field, a radio frequency transmit coil, and a single-sided gradient coil set. In accordance with various embodiments, the radio frequency transmit coil and the single-sided gradient coil set are positioned proximate to the front surface. In accordance with various embodiments, the system includes an electromagnet, a radio frequency receive coil, and a power source. In accordance with various embodiments, the power source is configured to flow current through at least one of the radio frequency transmit coil, the single-sided gradient coil set, or the electromagnet to generate an electromagnetic field in a region of interest. In accordance with various embodiments, the region of interest resides outside the front surface.

As shown in FIG. 7, the method S100 also includes executing a patient positioning protocol comprising running at least one first scan at step S120, running at least one second scan at step S130, reviewing the at least one second scan at step S140, and determining at least one path for conducting a biopsy based on review of the at least one second scan at step S150.

In accordance with various embodiments, the radio frequency transmit coil and the single-sided gradient coil set are located on the front surface. In accordance with various embodiments, the front surface is a concave surface. In accordance with various embodiments, the permanent magnet has an aperture through center of the permanent magnet. In accordance with various embodiments, the static magnetic field of the permanent magnet ranges from 1 mT to 1 T. In accordance with various embodiments, the static magnetic field of the permanent magnet ranges from 10 mT to 195 mT.

In accordance with various embodiments, the radio frequency transmit coil includes a first ring and a second ring that are connected via one or more capacitors and/or one or more rungs. In accordance with various embodiments, the radio frequency transmit coil is non-planar and oriented to partially surround the region of interest. In accordance with various embodiments, the single-sided gradient coil set is non-planar and oriented to partially surround the region of interest. In accordance with various embodiments, the single-sided gradient coil set is configured to project a magnetic field gradient to the region of interest. In accordance with various embodiments, the single-sided gradient coil set includes one or more first spiral coils at a first position and one or more second spiral coils at a second position, the first position and the second position being located opposite each other about a center region of the single-sided gradient coil set. In accordance with various embodiments, the single-sided gradient coil set has a rise time less than 10 μs.

In accordance with various embodiments, the electromagnet is configured to alter the static magnetic field of the permanent magnet within the region of interest. In accordance with various embodiments, the electromagnet has a magnetic field strength from 10 mT to 1 T. In accordance with various embodiments, the radio frequency receive coil is a flexible coil configured to be affixed to an anatomical portion of a patient for imaging within the region of interest. In accordance with various embodiments, the radio frequency receive coil is in one of a single-loop coil configuration, figure-8 coil configuration, or butterfly coil configuration, wherein the coil is smaller than the region of interest. In accordance with various embodiments, the radio frequency transmit coil and the single-sided gradient coil set are concentric about the region of interest. In accordance with various embodiments, the magnetic resonance imaging system is a single-sided magnetic resonance imaging system that comprises a bore having an opening positioned about a center region of the front surface.

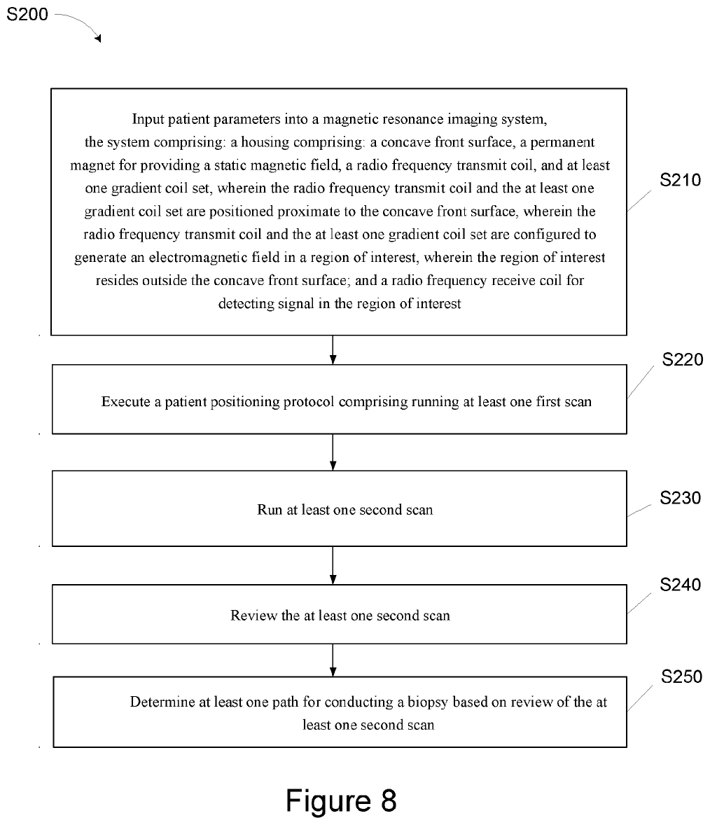

FIG. 8 is a flowchart for a method S200 of performing magnetic resonance imaging, according to various embodiments. In accordance with various embodiments, the method S200 includes inputting patient parameters into a magnetic resonance imaging system at step S210. In accordance with various embodiments, the system includes a housing having a concave front surface, a permanent magnet for providing a static magnetic field, a radio frequency transmit coil, and at least one gradient coil set. In accordance with various embodiments, the radio frequency transmit coil and the at least one gradient coil set are positioned proximate to the concave front surface. In accordance with various embodiments, the radio frequency transmit coil and the at least one gradient coil set are configured to generate an electromagnetic field in a region of interest. In accordance with various embodiments, the region of interest resides outside the concave front surface. In accordance with various embodiments, the system includes a radio frequency receive coil for detecting signal in the region of interest.

As shown in FIG. 8, the method S200 includes executing a patient positioning protocol comprising running at least one first scan at step S220, running at least one second scan at step S230, reviewing the at least one second scan at step S240, and determining at least one path for conducting a biopsy based on review of the at least one second scan at step S250.

In accordance with various embodiments, the radio frequency transmit coil and the single-sided gradient coil set are located on the concave front surface. In accordance with various embodiments, the static magnetic field of the permanent magnet ranges from 1 mT to 1 T. In accordance with various embodiments, the static magnetic field of the permanent magnet ranges from 10 mT to 195 mT. In accordance with various embodiments, the radio frequency transmit coil comprises a first ring and a second ring that are connected via one or more capacitors and/or one or more rungs. In accordance with various embodiments, the radio frequency transmit coil is non-planar and oriented to partially surround the region of interest. In accordance with various embodiments, the at least one gradient coil set is non-planar, single-sided, and oriented to partially surround the region of interest. In accordance with various embodiments, the at least one gradient coil set is configured to project magnetic field gradient in the region of interest.

In accordance with various embodiments, the at least one gradient coil set comprises one or more first spiral coils at a first position and one or more second spiral coils at a second position, the first position and the second position being located opposite each other about a center region of the at least one gradient coil set. In accordance with various embodiments, the at least one gradient coil set has a rise time less than 10 μs. In accordance with various embodiments, the permanent magnet has an aperture through center of the permanent magnet. In accordance with various embodiments, the system further includes an electromagnet configured to alter the static magnetic field of the permanent magnet within the region of interest. In accordance with various embodiments, the electromagnet has a magnetic field strength from 10 mT to 1 T. In accordance with various embodiments, the radio frequency receive coil is a flexible coil configured to be affixed to an anatomical portion of a patient for imaging within the region of interest. In accordance with various embodiments, the radio frequency receive coil is in one of a single-loop coil configuration, figure-8 coil configuration, or butterfly coil configuration, where the coil is smaller than the region of interest.

In accordance with various embodiments, the radio frequency transmit coil and the at least one gradient coil set are concentric about the region of interest. In accordance with various embodiments, the magnetic resonance imaging system is a single-sided magnetic resonance imaging system that comprises a magnetic resonance imaging scanner or a magnetic resonance imaging spectrometer.

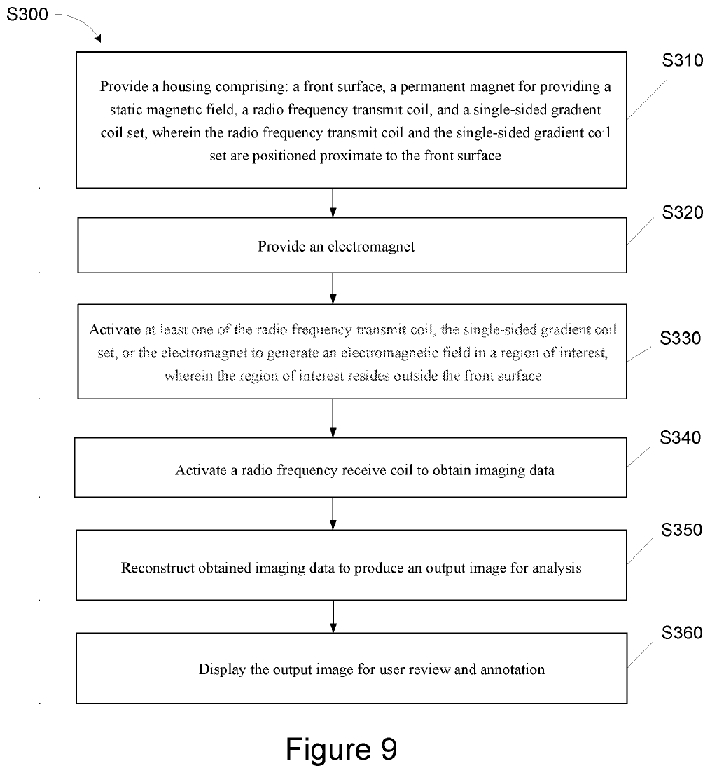

FIG. 9 is a flowchart for a method S300 of performing a scan on a magnetic resonance imaging system, according to various embodiments. In accordance with various embodiments, the method S300 includes at step S310 providing a housing having a front surface, a permanent magnet for providing a static magnetic field, a radio frequency transmit coil, and a single-sided gradient coil set. In accordance with various embodiments, the radio frequency transmit coil and the single-sided gradient coil set are positioned proximate to the front surface. In accordance with various embodiments, the method S300 includes providing an electromagnet at step S320. In accordance with various embodiments, the method S300 includes at step S330 activating at least one of the radio frequency transmit coil, the single-sided gradient coil set, or the electromagnet to generate an electromagnetic field in a region of interest. In accordance with various embodiments, the region of interest resides outside the front surface.

In accordance with various embodiments, the method S300 includes activating a radio frequency receive coil to obtain imaging data at step S340, reconstructing obtained imaging data to produce an output image for analysis at step S350, and displaying the output image for user review and annotation at step S360.

In accordance with various embodiments, the radio frequency transmit coil and the single-sided gradient coil set are located on the front surface. In accordance with various embodiments, the front surface is a concave surface. In accordance with various embodiments, the permanent magnet has an aperture through center of the permanent magnet. In accordance with various embodiments, the static magnetic field of the permanent magnet ranges from 1 mT to 1 T. In accordance with various embodiments, the static magnetic field of the permanent magnet ranges from 10 mT to 195 mT.

In accordance with various embodiments, the radio frequency transmit coil includes a first ring and a second ring that are connected via one or more capacitors and/or one or more rungs. In accordance with various embodiments, the radio frequency transmit coil is non-planar and oriented to partially surround the region of interest. In accordance with various embodiments, the single-sided gradient coil set is non-planar and oriented to partially surround the region of interest. In accordance with various embodiments, the single-sided gradient coil set is configured to project a magnetic field gradient to the region of interest. In accordance with various embodiments, the single-sided gradient coil set includes one or more first spiral coils at a first position and one or more second spiral coils at a second position, the first position and the second position being located opposite each other about a center region of the single-sided gradient coil set. In accordance with various embodiments, the single-sided gradient coil set has a rise time less than 10 μs.

In accordance with various embodiments, the electromagnet is configured to alter the static magnetic field of the permanent magnet within the region of interest. In accordance with various embodiments, the electromagnet has a magnetic field strength from 10 mT to 1 T. In accordance with various embodiments, the radio frequency receive coil is a flexible coil configured to be affixed to an anatomical portion of a patient for imaging within the region of interest. In accordance with various embodiments, the radio frequency receive coil is in one of a single-loop coil configuration, figure-8 coil configuration, or butterfly coil configuration, wherein the coil is smaller than the region of interest. In accordance with various embodiments, the radio frequency transmit coil and the single-sided gradient coil set are concentric about the region of interest. In accordance with various embodiments, the magnetic resonance imaging system is a single-sided magnetic resonance imaging system that comprises a bore having an opening positioned about a center region of the front surface.

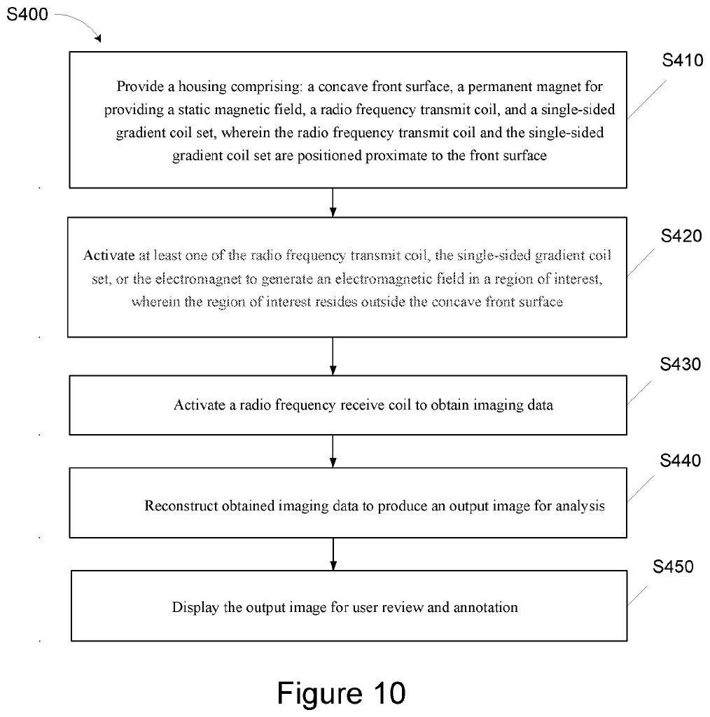

FIG. 10 is a flowchart for a method S400 of performing a scan on a magnetic resonance imaging system, according to various embodiments. In accordance with various embodiments, the method S400 includes at step S410 providing a housing having a concave front surface, a permanent magnet for providing a static magnetic field, a radio frequency transmit coil, and a single-sided gradient coil set. In accordance with various embodiments, the radio frequency transmit coil and the single-sided gradient coil set are positioned proximate to the front surface.

In accordance with various embodiments, the method S400 includes at step S420 activating at least one of the radio frequency transmit coil and the at least one gradient coil set to generate an electromagnetic field in a region of interest. In accordance with various embodiments, the region of interest resides outside the concave front surface.

In accordance with various embodiments, the method S400 includes activating a radio frequency receive coil to obtain imaging data at step S430, reconstructing obtained imaging data to produce an output image for analysis at step S440, and displaying the output image for user review and annotation at step S450.

In accordance with various embodiments, the radio frequency transmit coil and the single-sided gradient coil set are located on the concave front surface. In accordance with various embodiments, the static magnetic field of the permanent magnet ranges from 1 mT to 1 T. In accordance with various embodiments, the static magnetic field of the permanent magnet ranges from 10 mT to 195 mT. In accordance with various embodiments, the radio frequency transmit coil comprises a first ring and a second ring that are connected via one or more capacitors and/or one or more rungs. In accordance with various embodiments, the radio frequency transmit coil is non-planar and oriented to partially surround the region of interest. In accordance with various embodiments, the at least one gradient coil set is non-planar, single-sided, and oriented to partially surround the region of interest. In accordance with various embodiments, the at least one gradient coil set is configured to project magnetic field gradient in the region of interest.

In accordance with various embodiments, the at least one gradient coil set comprises one or more first spiral coils at a first position and one or more second spiral coils at a second position, the first position and the second position being located opposite each other about a center region of the at least one gradient coil set. In accordance with various embodiments, the at least one gradient coil set has a rise time less than 10 μs. In accordance with various embodiments, the permanent magnet has an aperture through center of the permanent magnet. In accordance with various embodiments, the system further includes an electromagnet configured to alter the static magnetic field of the permanent magnet within the region of interest. In accordance with various embodiments, the electromagnet has a magnetic field strength from 10 mT to 1 T. In accordance with various embodiments, the radio frequency receive coil is a flexible coil configured to be affixed to an anatomical portion of a patient for imaging within the region of interest. In accordance with various embodiments, the radio frequency receive coil is in one of a single-loop coil configuration, figure-8 coil configuration, or butterfly coil configuration, where the coil is smaller than the region of interest.

In accordance with various embodiments, the radio frequency transmit coil and the at least one gradient coil set are concentric about the region of interest. In accordance with various embodiments, the magnetic resonance imaging system is a single-sided magnetic resonance imaging system that comprises a magnetic resonance imaging scanner or a magnetic resonance imaging spectrometer.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

Patient Intake

As discussed herein, and in accordance with various embodiments, the various workflows or methods, and various combinations of steps that make up the various workflow or method embodiments, can also include a patient intake step.

As part of this step, and any all relevant information can be part of the patient intake step, including the intake of all data relevant to the performance of the magnetic resonance system, in accordance with various embodiments herein.

In accordance with various embodiments, the patient intake step can include, not only data inputted by user, but also data downloaded from any memory source, whether it be, for example, data from a remote data storage component (e.g., the cloud), an on-board data storage component, or portable data storage component (e.g., external flash/solid state drives and external hard drives).

In accordance with various embodiments, and further related to memory sources, an on-board data storage component (e.g., on-board a computing system within an MRI system) can be a random access memory (RAM) or other dynamic memory, or a read only memory (ROM) or other static storage device.

In accordance with various embodiments, and further related to memory sources, a remote or portable data storage component can include, for example, a magnetic disk, optical disk, solid state drive (SSD), and a media drive and a removable storage interface. A media drive may include a drive or other mechanism to support fixed or removable storage media, such as a hard disk drive, a floppy disk drive, a magnetic tape drive, an optical disk drive, a CD or DVD drive (R or RW), flash drive, or other removable or fixed media drive. As these examples illustrate, the storage media may include a computer-readable storage medium having stored therein particular computer software, instructions, or data.

In accordance with various embodiments, a storage device may include other similar instrumentalities for allowing computer programs or other instructions or data to be loaded into computing system. Such instrumentalities may include, for example, a removable storage unit and an interface, such as a program cartridge and cartridge interface, a removable memory (for example, a flash memory or other removable memory module) and memory slot, and other removable storage units and interfaces that allow software and data to be transferred from the storage device to computing system.

In accordance with various embodiments, the data types that can be user inputted, uploaded, downloaded, etc., can include, for example, patient name, patient sex, patient weight, patient height, patient contact information, patient birthdate, patient's referring physician, and patient race. In addition, a clinical baseline can be user inputted that includes information such as the patient's Gleason score for any past biopsies, the frequency of sexual intercourse, the last time the patient had food, and the patient's PSA level.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

Patient Positioning

As discussed herein, and in accordance with various embodiments, the various workflows or methods, and various combinations of steps that make up the various workflow or method embodiments, can also include a patient positioning step.

As a precursor to the positioning, a patient will generally undergo a patient preparation and screening process, whereby the patient is screened for foreign bodies and devices such as pacemakers that may represent a contraindication to imaging. The patient's important health conditions, including allergies, as well as patient data received as part of the patient intake process, are also reviewed.

For positioning in standard full-body MRIs, a patient would generally be placed on a table, usually in the supine position. Receiver imaging coils are arranged around the body part of interest (head, chest, knee, etc.) If EKG or respiratory gating is required, then these devices are attached at this time. A key anatomic structure such as the bridge of the nose or umbilicus is identified as a landmark using laser guidance, and this is correlated with table position by pressing a button on the gantry.

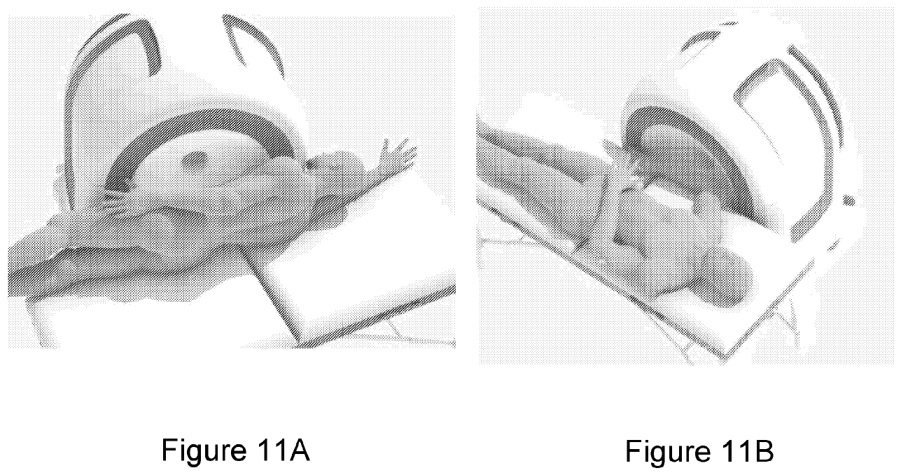

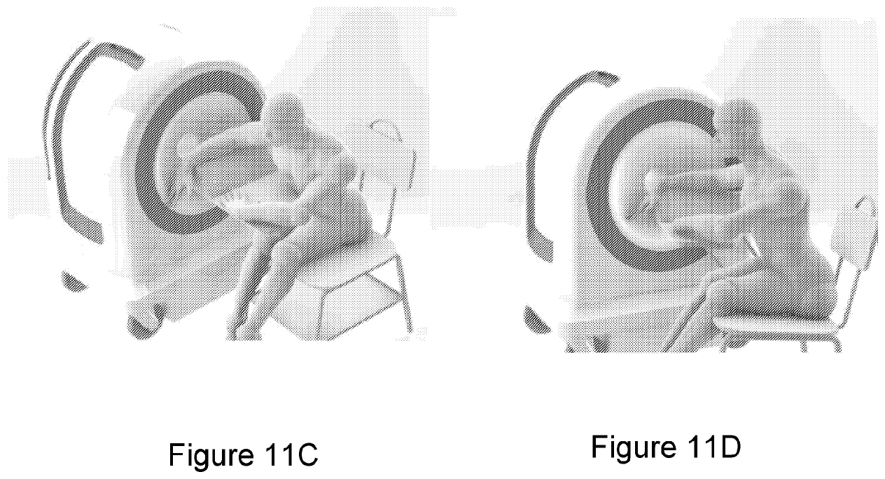

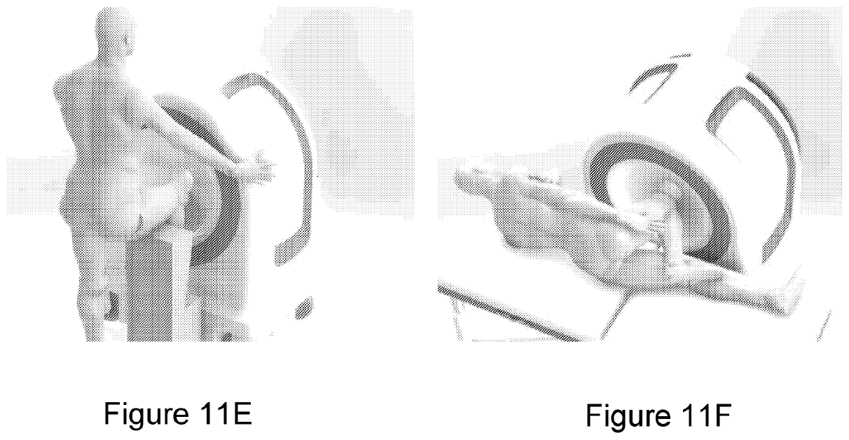

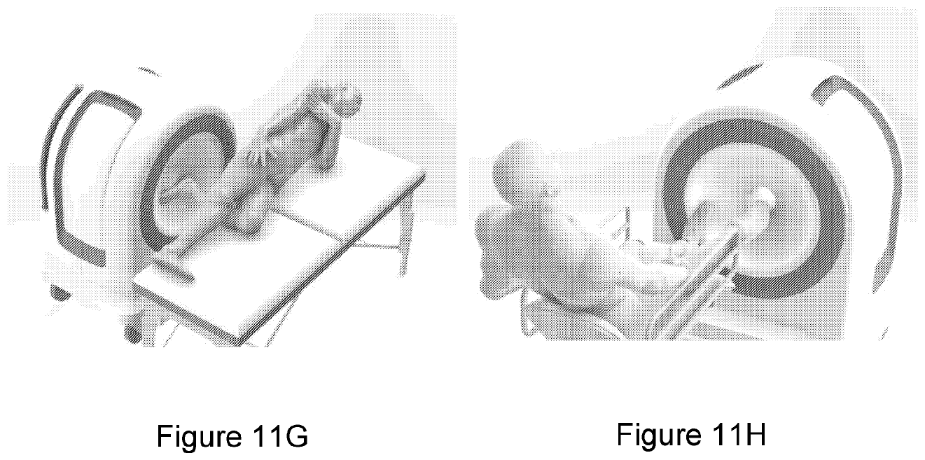

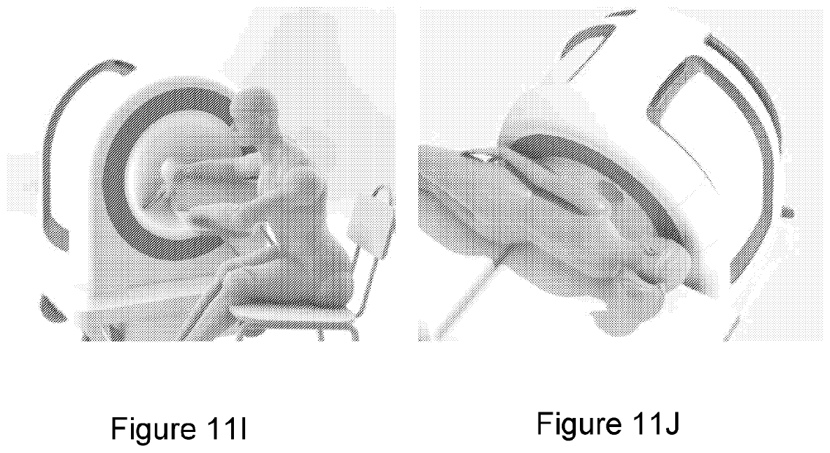

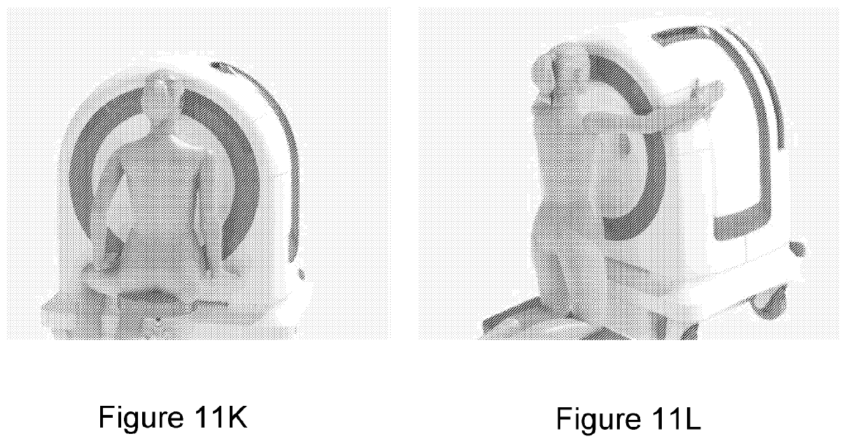

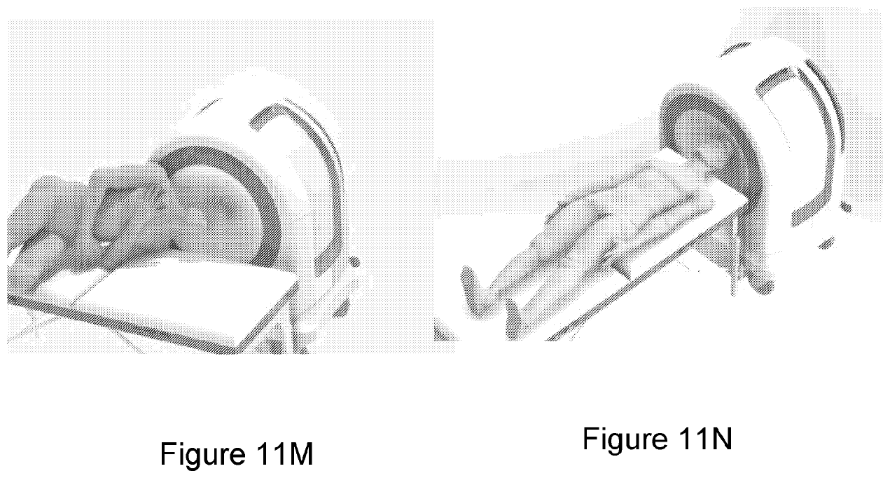

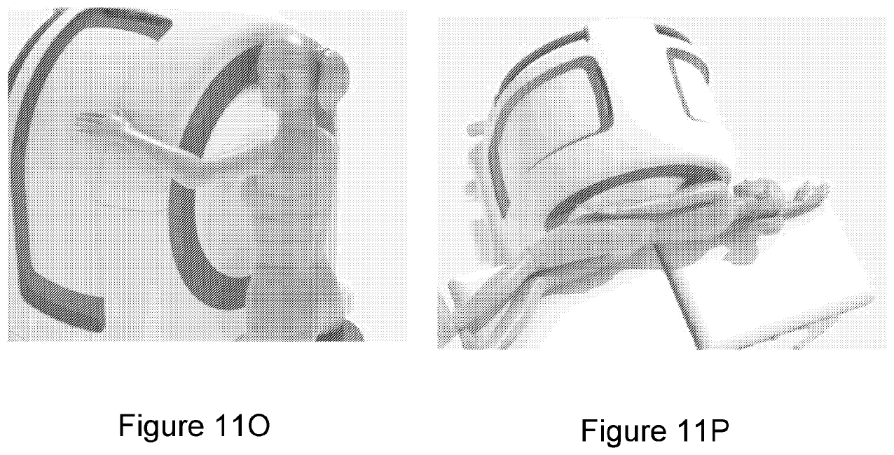

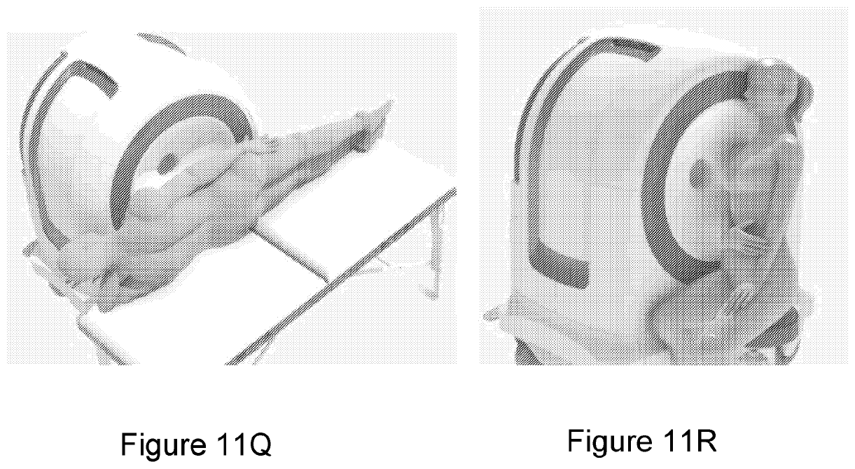

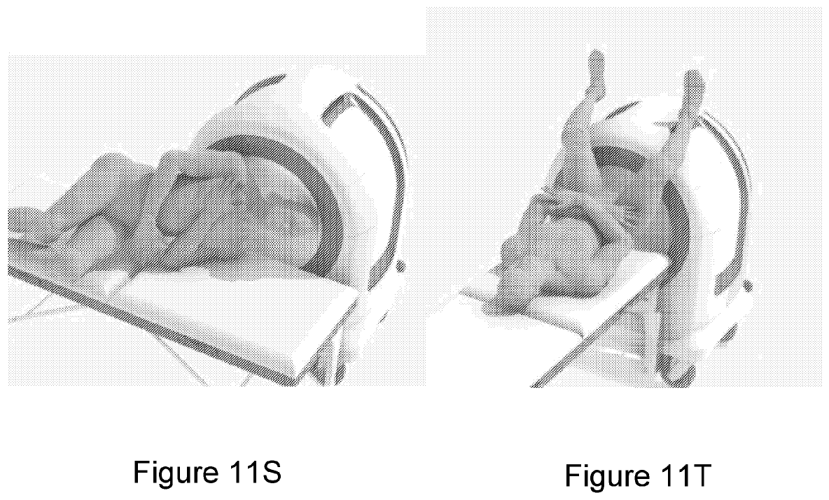

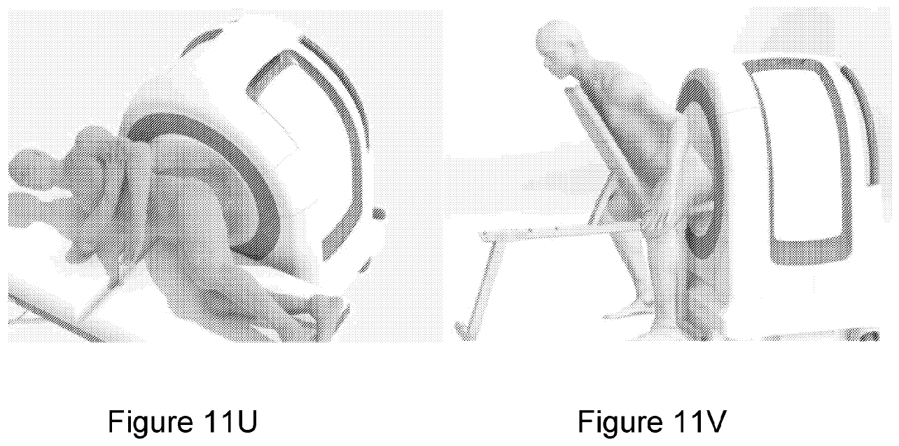

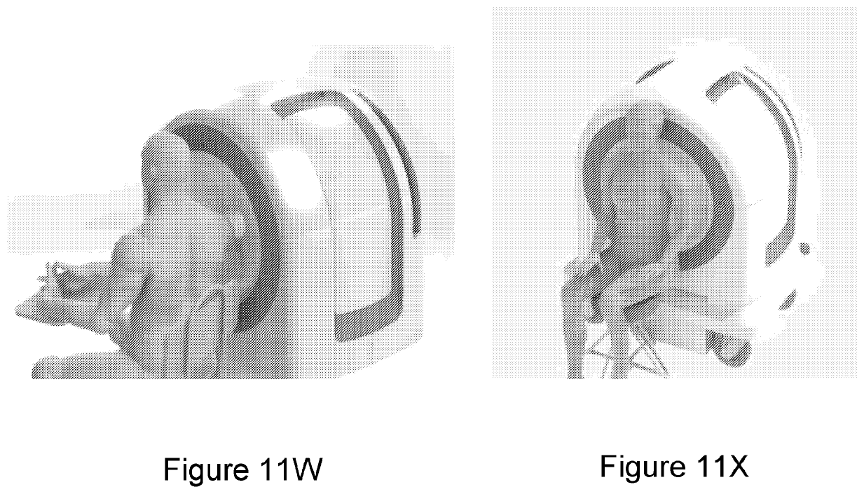

In accordance with various embodiments, using the example system illustrated in FIGS. 11A-11X as a basis herein, a patient is positioned in any number of different positions depending on the type of anatomical scan.

As illustrated in FIG. 11A, when the abdomen is the region scanned, the patient can be laid on a surface at a lateral position. As illustrated, for the abdominal scan, a patient can be positioned to lay sideways facing the bore, with the arm closest to the table stretched out and the other at the side of the body. The abdomen region can be positioned such that it is directly in front of the bore.

As illustrated in FIG. 11B, when an appendage (e.g., arm or hand) is the region scanned, the patient can be laid on a surface at a supine position. As illustrated, for the appendage scan, a patient can be positioned to be laid down with the arm or hand to be scanned situated directly in front of the bore.

As illustrated in FIG. 11C, when an appendage (e.g., arm or hand) is the region scanned, the patient can also be placed at a seated position. As illustrated, for the appendage scan, a patient can be positioned to be seated with arm to be scanned raised up against the system such that it is situated directly in front of the bore.

As illustrated in FIG. 11D, when an appendage (e.g., elbow) is the region scanned, the patient can also be placed at a seated position. As illustrated, for the appendage scan, a patient can be positioned to be seated with elbow to be scanned raised up against the system such that it is situated directly in front of the bore and the other arm resting comfortably.

As illustrated in FIG. 11E, when an appendage (e.g., knee) is the region scanned, the patient can also be situated to stand with the one leg lifted that is to be scanned. As illustrated, for the appendage scan, a patient can be positioned to be standing and facing the bore such that the leg of interest is lifted with the knee resting directly in front of the bore and the other leg placed firmly on the ground for stability.

As illustrated in FIG. 11F, when an appendage (e.g., knee) is the region scanned, the patient can also be situated in a lateral position. As illustrated, for the appendage scan, a patient can be positioned to lay sideways facing the bore, with the leg of interest bent and the other leg resting on the table and extended out. The patient's knee can be placed such that it is directly in front of the bore.

As illustrated in FIG. 11G, when an appendage (e.g., foot) is the region scanned, the patient can also be situated in a lateral position. As illustrated, for the appendage scan, a patient can be positioned to lay sideways facing away from the bore, with the leg of interest bent and resting on the table and the other leg extended out. The patient's foot can be placed such that it is directly in front of the bore.

As illustrated in FIG. 11H, when an appendage (e.g., foot) is the region scanned, the patient can also be situated in a seated position. As illustrated, for the appendage scan, a patient can be positioned to be seated facing the bore, with the leg of interest extended out toward the bore and the other leg resting comfortably. The patient's foot can be placed such that it is directly in front of the bore.

As illustrated in FIG. 11I, when an appendage (e.g., wrist) is the region scanned, the patient can be situated in a seated position. As illustrated, for the appendage scan, a patient can be positioned to be seated parallel to the system, such that the wrist of interest is directly in front of the bore with and the other arm is resting comfortably to the side.

As illustrated in FIG. 11J, when the breast is the region scanned, the patient can be laid on a surface in a lateral position. As illustrated, for the breast scan, a patient can be positioned to lay sideways facing the bore, with one arm extended out above the head and the other hand resting to the side of the body. The breast region can be positioned to be directly in front of the bore.

As illustrated in FIG. 11K, when the breast is the region scanned, the patient can also be placed at a seated position. As illustrated, for the breast scan, a patient can be positioned to be seated and facing the bore such that arms are extended out and resting on the top of the system. The breast region can be positioned to be directly in front of the bore.

As illustrated in FIG. 11L, when the breast is the region scanned, the patient can also be placed at a kneeling position. As illustrated, for the breast scan, a patient can be positioned to be kneeling and facing the bore such that arms are extended out and resting on the top of the system. The breast region can be positioned to be directly in front of the bore.

As illustrated in FIG. 11M, when the head is the region scanned, the patient can be laid on a surface at a lateral position. As illustrated, for the head scan, a patient can be positioned to lay sideways facing away from the bore, with the head placed directly in front of the bore.

As illustrated in FIG. 11N, when the head is the region scanned, the patient can also be laid on a surface at a supine position. As illustrated, for the head scan, a patient can be positioned to lay down face up, with the top of the head against the system, such that it is situated directly in front of the bore.

As illustrated in FIG. 11O, when the heart is the region scanned, the patient can be placed at a seated or standing position. As illustrated, for the heart scan, a patient can be positioned to be seated facing the bore such that the heart region is situated directly in front of the bore.

As illustrated in FIG. 11P, when the kidney is the region scanned, the patient can be laid on a surface at a lateral position. As illustrated, for the kidney scan, a patient can be positioned to lay sideways facing the bore, with the arm closest to the table stretched out and the other at the side of the body. The kidney region can be positioned such that it is directly in front of the bore.

As illustrated in FIG. 11Q, when the liver is the region scanned, the patient can be laid on a surface at a lateral position. As illustrated, for the liver scan, a patient can be positioned to lay sideways facing the bore, with the arm closest to the table stretched out or bent to rest the head, and the other at the side of the body. The liver region can be positioned such that it is directly in front of the bore.

As illustrated in FIG. 11R, when the lung is the region scanned, the patient can be placed at a seated position. As illustrated, for the lung scan, a patient can be positioned to be seated facing away from the bore such that the lung region is situated directly in front of the bore.

As illustrated in FIG. 11S, when the neck is the region scanned, the patient can be laid on a surface at a lateral position. As illustrated, for the neck scan, a patient can be positioned to lay sideways and face away from the bore. The neck region can be positioned to be directly in front of the bore.

As illustrated in FIG. 11T, when the pelvis is the region scanned, the patient can be laid on a surface at a lithotomy position. As illustrated, for the pelvic scan, a patient can be positioned to have their back resting on the table and legs raised up to be resting against the top of the system. The pelvic region can be positioned to be directly in front of the bore.

As illustrated in FIG. 11U, when the pelvis is the region scanned, the patient can also be laid on a surface at a lateral position. As illustrated, for the pelvic scan, a patient can be positioned to lay sideways and face away from the bore. The pelvic region of the body can be positioned to be directly in front of the bore.

As illustrated in FIG. 11V, when the pelvis is the region scanned, the patient can also be placed at a prone position. As illustrated, for the pelvic scan, a patient can be positioned to rest with the chest against a surface, facing away from the bore. The pelvic region can be positioned such that it is directly in front of the bore.

As illustrated in FIG. 11W, when the shoulder is the region scanned, the patient can be placed at a seated position. As illustrated, for the shoulder scan, a patient can be positioned to be seated next to the system with the shoulder to be scanned situated directly in front of the bore.

As illustrated in FIG. 11X, when the spine is the region scanned, the patient can be placed at a seated position. As illustrated, for the spine scan, a patient can be positioned to be seated with back facing away from the bore and spine situated directly in view of the bore.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

Biopsy Guidance

As discussed herein, and in accordance with various embodiments, the various workflows or methods, and various combinations of steps that make up the various workflow or method embodiments, can also include biopsy guidance using the disclosed MRI system.

In accordance with various embodiments, the procedure for biopsy guidance using the disclosed MRI system may include one from the list of medical procedures consisting of transperineal biopsy, transperineal LDR brachytherapy, transperineal HDR brachytherapy, transperineal laser ablation, transperineal cryoablation, transrectal HIFU, breast biopsies, deep brain stimulation (DBS), brain biopsy, liver biopsy, kidney biopsy, lung biopsy, coronary stent insertion, brain stent insertion, and intensity modulated radiation treatment guidance.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

Calibration

As discussed herein, and in accordance with various embodiments, the various workflows or methods, and various combinations of steps that make up the various workflow or method embodiments, can also include a calibration step.

Calibration can take many forms of processes. Generally, calibration involves running a full scan, similar to the scan run on a patient, in order to ensure image quality. In accordance with various embodiments, after a predetermined period, a user can be prompted to initiate a calibration routine such as, for example, a RF calibration routine. As part of initiating a calibration, a calibration phantom is positioned to allow calibration to advance. A calibration phantom can take many forms. Generally, a calibration phantom can be an object (usually an artificial object) of known size and composition that is imaged to test, adjust or monitor an MRI systems homogeneity, imaging performance and orientation aspects. A phantom can be a fluid-filled container or bottle often filled with a plastic structure of various sizes and shapes.

RF Calibration routine, in particular, optimizes RF pulse parameters such as, for example, signal power, signal duration and signal bandwidth to ensure image quality. The calibration routine acquires signal data from a calibration phantom using a predetermined set of parameters and sequence. Calibration data can be processed to determine the parameter set that should be used during imaging scans.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature.

Pre-Polarizer

As discussed herein, and in accordance with various embodiments, the various workflows or methods, and various combinations of steps that make up the various workflow or method embodiments, can also include a pre-polarization step.

In some embodiments, the prepolarizer can be charged by a system power supply. The powering of this polarizer would temporarily change the magnetic field within the field of view either by increasing or decreasing the main magnetic field strength. This change in the magnetic field then creates a change in the total number of nuclear spins that are aligned within the field of view and it changes the time constants by which the nuclear spins relax. An increase in the field allows for more nuclear spins to be aligned with the field, thus temporarily increasing the signal from a given voxel. A decrease in the field changes the relaxation properties of the objects and could allow for increased contrast within the field of view.

In accordance with various embodiments, the prepolarizer might be first charged to increase the field strength and therefore the signal strength. Then after waiting an appropriate amount of time for the nuclear spins to align (as dictated by the T1 time of the desired spins), the prepolarizer can be removed. As this prepolarizer is depowered, the spins that are aligned will begin to relax and loose energy but can still be imaged by the magnetic resonance system at an increased signal level than when the system did not apply a prepolarizing pulse.

It should be understood that any use of subheadings herein are for organizational purposes, and should not be read to limit the application of those subheaded features to the various embodiments herein. Each and every feature described herein is applicable and usable in all the various embodiments discussed herein and that all features described herein can be used in any contemplated combination, regardless of the specific example embodiments that are described herein. It should further be noted that exemplary description of specific features are used, largely for informational purposes, and not in any way to limit the design, subfeature, and functionality of the specifically described feature

### RECITATION OF EMBODIMENTS

1. A magnetic resonance imaging system comprising: a housing comprising: a front surface, a permanent magnet for providing a static magnetic field, a radio frequency transmit coil, and a single-sided gradient coil set, wherein the radio frequency transmit coil and the single-sided gradient coil set are positioned proximate to the front surface; an electromagnet; a radio frequency receive coil; and a power source, wherein the power source is configured to flow current through at least one of the radio frequency transmit coil, the single-sided gradient coil set, or the electromagnet to generate an electromagnetic field in a region of interest, wherein the region of interest resides outside the front surface.

2. The system of embodiment 1, wherein the radio frequency transmit coil and the single-sided gradient coil set are located on the front surface.

3. The system of anyone of embodiments 1-2, wherein the front surface is a concave surface.

4. The system of anyone of embodiments 1-3, wherein the permanent magnet has an aperture through center of the permanent magnet.

5. The system of anyone of embodiments 1-4, wherein the static magnetic field of the permanent magnet ranges from 1 mT to 1 T.

5-1. The system of anyone of embodiments 1-4, wherein the static magnetic field of the permanent magnet ranges from 10 mT to 195 mT.

6. The system of anyone of embodiments 1-5, wherein the radio frequency transmit coil comprises a first ring and a second ring that are connected via one or more capacitors and/or one or more rungs.

7. The system of anyone of embodiments 1-6, wherein the radio frequency transmit coil is non-planar and oriented to partially surround the region of interest.

8. The system of anyone of embodiments 1-7, wherein the single-sided gradient coil set is non-planar and oriented to partially surround the region of interest, and wherein the single-sided gradient coil set is configured to project a magnetic field gradient to the region of interest.

9. The system of anyone of embodiments 1-8, wherein the single-sided gradient coil set comprises one or more first spiral coils at a first position and one or more second spiral coils at a second position, the first position and the second position being located opposite each other about a center region of the single-sided gradient coil set.

10. The system of anyone of embodiments 1-9, wherein the single-sided gradient coil set has a rise time less than 10 μs.

11. The system of anyone of embodiments 1-10, wherein the electromagnet is configured to alter the static magnetic field of the permanent magnet within the region of interest.

12. The system of anyone of embodiments 1-11, wherein the electromagnet has a magnetic field strength from 10 mT to 1 T.

13. The system of anyone of embodiments 1-12, wherein the radio frequency receive coil is a flexible coil configured to be affixed to an anatomical portion of a patient for imaging within the region of interest.

14. The system of anyone of embodiments 1-13, wherein the radio frequency receive coil is in one of a single-loop coil configuration, figure-8 coil configuration, or butterfly coil configuration, wherein the coil is smaller than the region of interest.

15. The system of anyone of embodiments 1-14, wherein the radio frequency transmit coil and the single-sided gradient coil set are concentric about the region of interest.

16. The system of anyone of embodiments 1-15, wherein the magnetic resonance imaging system is a single-sided magnetic resonance imaging system that comprises a bore having an opening positioned about a center region of the front surface.

17. A magnetic resonance imaging system comprising: a housing comprising: a concave front surface, a permanent magnet for providing a static magnetic field, a radio frequency transmit coil, and at least one gradient coil set, wherein the radio frequency transmit coil and the at least one gradient coil set are positioned proximate to the concave front surface, wherein the radio frequency transmit coil and the at least one gradient coil set are configured to generate an electromagnetic field in a region of interest, wherein the region of interest resides outside the concave front surface; and a radio frequency receive coil for detecting signal in the region of interest.

18. The system of embodiment 17, wherein the radio frequency transmit coil and the at least one gradient coil set are located on the concave front surface.

19. The system of anyone of embodiments 17-18, wherein the static magnetic field of the permanent magnet ranges from 1 mT to 1 T.

20. The system of anyone of embodiments 17-19, wherein the static magnetic field of the permanent magnet ranges from 10 mT to 195 mT.

21. The system of anyone of embodiments 17-20, wherein the radio frequency transmit coil comprises a first ring and a second ring that are connected via one or more capacitors and/or one or more rungs.

22. The system of anyone of embodiments 17-21, wherein the radio frequency transmit coil is non-planar and oriented to partially surround the region of interest.

23. The system of anyone of embodiments 17-22, wherein the at least one gradient coil set is non-planar, single-sided, and oriented to partially surround the region of interest, and wherein the at least one gradient coil set is configured to project magnetic field gradient in the region of interest.

24. The system of anyone of embodiments 17-23, wherein the at least one gradient coil set comprises one or more first spiral coils at a first position and one or more second spiral coils at a second position, the first position and the second position being located opposite each other about a center region of the at least one gradient coil set.

25. The system of anyone of embodiments 17-24, wherein the at least one gradient coil set has a rise time less than 10 μs.

26. The system of anyone of embodiments 17-25, wherein the permanent magnet has an aperture through center of the permanent magnet.

27. The system of anyone of embodiments 17-26, further comprising: an electromagnet configured to alter the static magnetic field of the permanent magnet within the region of interest.

28. The system of anyone of embodiments 17-27, wherein the radio frequency receive coil is a flexible coil configured to be affixed to an anatomical portion of a patient for imaging within the region of interest.

29. The system of anyone of embodiments 17-28, wherein the radio frequency receive coil is in one of a single-loop coil configuration, figure-8 coil configuration, or butterfly coil configuration, where the coil is smaller than the region of interest.

30. The system of anyone of embodiments 17-29, wherein the radio frequency transmit coil and the at least one gradient coil set are concentric about the region of interest.

31. The system of embodiment 27, wherein the electromagnet has a magnetic field strength from 10 mT to 1 T.

32. The system of anyone of embodiments 17-31, wherein the magnetic resonance imaging system is a single-sided magnetic resonance imaging system that comprises a magnetic resonance imaging scanner or a magnetic resonance imaging spectrometer.

33. A method of performing magnetic resonance imaging comprising: inputting patient parameters into a magnetic resonance imaging system, the system comprising: a housing comprising: a front surface, a permanent magnet for providing a static magnetic field, a radio frequency transmit coil, and a single-sided gradient coil set, wherein the radio frequency transmit coil and the single-sided gradient coil set are positioned proximate to the front surface; an electromagnet; a radio frequency receive coil; and a power source, wherein the power source is configured to flow current through at least one of the radio frequency transmit coil, the single-sided gradient coil set, or the electromagnet to generate an electromagnetic field in a region of interest, wherein the region of interest resides outside the front surface; executing a patient positioning protocol comprising running at least one first scan; running at least one second scan; reviewing the at least one second scan; and determining at least one path for conducting a biopsy based on review of the at least one second scan.

34. The method of embodiment 33, wherein the radio frequency transmit coil and the single-sided gradient coil set are located on the front surface.

35. The method of anyone of embodiments 33-34, wherein the front surface is a concave surface.

36. The method of anyone of embodiments 33-35, wherein the permanent magnet has an aperture through center of the permanent magnet.

37. The method of anyone of embodiments 33-36, wherein the static magnetic field of the permanent magnet ranges from 1 mT to 1 T.

37-1. The method of anyone of embodiments 33-36, wherein the static magnetic field of the permanent magnet ranges from 10 mT to 195 mT.

38. The method of anyone of embodiments 33-37, wherein the radio frequency transmit coil comprises a first ring and a second ring that are connected via one or more capacitors and/or one or more rungs.

39. The method of anyone of embodiments 33-38, wherein the radio frequency transmit coil is non-planar and oriented to partially surround the region of interest.

40. The method of anyone of embodiments 33-39, wherein the single-sided gradient coil set is non-planar and oriented to partially surround the region of interest, and wherein the single-sided gradient coil set is configured to project a magnetic field gradient to the region of interest.

41. The method of anyone of embodiments 33-40, wherein the single-sided gradient coil set comprises one or more first spiral coils at a first position and one or more second spiral coils at a second position, the first position and the second position being located opposite each other about a center region of the single-sided gradient coil set.

42. The method of anyone of embodiments 33-41, wherein the single-sided gradient coil set has a rise time less than 10 μs.

43. The method of anyone of embodiments 33-42, wherein the electromagnet is configured to alter the static magnetic field of the permanent magnet within the region of interest.

44. The method of anyone of embodiments 33-43, wherein the electromagnet has a magnetic field strength from 10 mT to 1 T.

45. The method of anyone of embodiments 33-44, wherein the radio frequency receive coil is a flexible coil configured to be affixed to an anatomical portion of a patient for imaging within the region of interest.

46. The method of anyone of embodiments 33-45, wherein the radio frequency receive coil is in one of a single-loop coil configuration, figure-8 coil configuration, or butterfly coil configuration, wherein the coil is smaller than the region of interest.

47. The method of anyone of embodiments 33-46, wherein the radio frequency transmit coil and the single-sided gradient coil set are concentric about the region of interest.

48. The method of anyone of embodiments 33-47, wherein the magnetic resonance imaging system is a single-sided magnetic resonance imaging system that comprises a bore having an opening positioned about a center region of the front surface.

49. A method of performing magnetic resonance imaging comprising: inputting patient parameters into a magnetic resonance imaging system, the system comprising: a housing comprising: a concave front surface, a permanent magnet for providing a static magnetic field, a radio frequency transmit coil, and at least one gradient coil set, wherein the radio frequency transmit coil and the at least one gradient coil set are positioned proximate to the concave front surface, wherein the radio frequency transmit coil and the at least one gradient coil set are configured to generate an electromagnetic field in a region of interest, wherein the region of interest resides outside the concave front surface; and a radio frequency receive coil for detecting signal in the region of interest; executing a patient positioning protocol comprising running at least one first scan; running at least one second scan; reviewing the at least one second scan; and determining at least one path for conducting a biopsy based on review of the at least one second scan.

50. The method of embodiment 49, wherein the radio frequency transmit coil and the at least one gradient coil set are located on the concave front surface.

51. The method of anyone of embodiments 49-50, wherein the static magnetic field of the permanent magnet ranges from 1 mT to 1 T.

52. The method of anyone of embodiments 49-51, wherein the static magnetic field of the permanent magnet ranges from 10 mT to 195 mT.

53. The method of anyone of embodiments 49-52, wherein the radio frequency transmit coil comprises a first ring and a second ring that are connected via one or more capacitors and/or one or more rungs.

54. The method of anyone of embodiments 49-53, wherein the radio frequency transmit coil is non-planar and oriented to partially surround the region of interest.

55. The method of anyone of embodiments 49-54, wherein the at least one gradient coil set is non-planar, single-sided, and oriented to partially surround the region of interest, and wherein the at least one gradient coil set is configured to project magnetic field gradient in the region of interest.

56. The method of anyone of embodiments 49-55, wherein the at least one gradient coil set comprises one or more first spiral coils at a first position and one or more second spiral coils at a second position, the first position and the second position being located opposite each other about a center region of the at least one gradient coil set.

57. The method of anyone of embodiments 49-56, wherein the at least one gradient coil set has a rise time less than 10 μs.

58. The method of anyone of embodiments 49-57, wherein the permanent magnet has an aperture through center of the permanent magnet.

59. The method of anyone of embodiments 49-58, further comprising: an electromagnet configured to alter the static magnetic field of the permanent magnet within the region of interest.

60. The method of anyone of embodiments 49-59, wherein the radio frequency receive coil is a flexible coil configured to be affixed to an anatomical portion of a patient for imaging within the region of interest.

61. The method of anyone of embodiments 49-60, wherein the radio frequency receive coil is in one of a single-loop coil configuration, figure-8 coil configuration, or butterfly coil configuration, where the coil is smaller than the region of interest.

62. The method of anyone of embodiments 49-61, wherein the radio frequency transmit coil and the at least one gradient coil set are concentric about the region of interest.

63. The method of embodiment 59, wherein the electromagnet has a magnetic field strength from 10 mT to 1 T.

64. The method of anyone of embodiments 49-63, wherein the magnetic resonance imaging system is a single-sided magnetic resonance imaging system that comprises a magnetic resonance imaging scanner or a magnetic resonance imaging spectrometer.

65. A method of performing a scan on a magnetic resonance imaging system comprising: providing a housing comprising: a front surface, a permanent magnet for providing a static magnetic field, a radio frequency transmit coil, and a single-sided gradient coil set, wherein the radio frequency transmit coil and the single-sided gradient coil set are positioned proximate to the front surface; providing an electromagnet; activating at least one of the radio frequency transmit coil, the single-sided gradient coil set, or the electromagnet to generate an electromagnetic field in a region of interest, wherein the region of interest resides outside the front surface; activating a radio frequency receive coil to obtain imaging data; reconstructing obtained imaging data to produce an output image for analysis; and displaying the output image for user review and annotation.

66. The method of embodiment 65, wherein the radio frequency transmit coil and the single-sided gradient coil set are located on the front surface.

67. The method of anyone of embodiments 65-66, wherein the front surface is a concave surface.

68. The method of anyone of embodiments 65-67, wherein the permanent magnet has an aperture through center of the permanent magnet.

69. The method of anyone of embodiments 65-68, wherein the static magnetic field of the permanent magnet ranges from 1 mT to 1 T.

69-1. The method of anyone of embodiments 65-68, wherein the static magnetic field of the permanent magnet ranges from 10 mT to 195 mT.

70. The method of anyone of embodiments 65-69, wherein the radio frequency transmit coil comprises a first ring and a second ring that are connected via one or more capacitors and/or one or more rungs.

71. The method of anyone of embodiments 65-70, wherein the radio frequency transmit coil is non-planar and oriented to partially surround the region of interest.

72. The method of anyone of embodiments 65-71, wherein the single-sided gradient coil set is non-planar and oriented to partially surround the region of interest, and wherein the single-sided gradient coil set is configured to project a magnetic field gradient to the region of interest.

73. The method of anyone of embodiments 65-72, wherein the single-sided gradient coil set comprises one or more first spiral coils at a first position and one or more second spiral coils at a second position, the first position and the second position being located opposite each other about a center region of the single-sided gradient coil set.

74. The method of anyone of embodiments 65-73, wherein the single-sided gradient coil set has a rise time less than 10 μs.

75. The method of anyone of embodiments 65-74, wherein the electromagnet is configured to alter the static magnetic field of the permanent magnet within the region of interest.

76. The method of anyone of embodiments 65-75, wherein the electromagnet has a magnetic field strength from 10 mT to 1 T.

77. The method of anyone of embodiments 65-76, wherein the radio frequency receive coil is a flexible coil configured to be affixed to an anatomical portion of a patient for imaging within the region of interest.

78. The method of anyone of embodiments 65-77, wherein the radio frequency receive coil is in one of a single-loop coil configuration, figure-8 coil configuration, or butterfly coil configuration, wherein the coil is smaller than the region of interest.

79. The method of anyone of embodiments 65-78, wherein the radio frequency transmit coil and the single-sided gradient coil set are concentric about the region of interest.

80. The method of anyone of embodiments 65-79, wherein the magnetic resonance imaging system is a single-sided magnetic resonance imaging system that comprises a bore having an opening positioned about a center region of the front surface.

81. A method of performing a scan on a magnetic resonance imaging system comprising: providing a housing comprising: a concave front surface, a permanent magnet for providing a static magnetic field, a radio frequency transmit coil, and at least one gradient coil set, wherein the radio frequency transmit coil and the at least one gradient coil set are positioned proximate to the front surface; activating at least one of the radio frequency transmit coil and the at least one gradient coil set to generate an electromagnetic field in a region of interest, wherein the region of interest resides outside the concave front surface; activating a radio frequency receive coil to obtain imaging data; reconstructing obtained imaging data to produce an output image for analysis; and displaying the output image for user review and annotation.

82. The method of embodiment 81, wherein the radio frequency transmit coil and the at least one gradient coil set are located on the concave front surface.

83. The method of anyone of embodiments 81-82, wherein the static magnetic field of the permanent magnet ranges from 1 mT to 1 T.

84. The method of anyone of embodiments 81-83, wherein the static magnetic field of the permanent magnet ranges from 10 mT to 195 mT.

85. The method of anyone of embodiments 81-84, wherein the radio frequency transmit coil comprises a first ring and a second ring that are connected via one or more capacitors and/or one or more rungs.

86. The method of anyone of embodiments 81-85, wherein the radio frequency transmit coil is non-planar and oriented to partially surround the region of interest.

87. The method of anyone of embodiments 81-86, wherein the at least one gradient coil set is non-planar, single-sided, and oriented to partially surround the region of interest, and wherein the at least one gradient coil set is configured to project magnetic field gradient in the region of interest.

88. The method of anyone of embodiments 81-87, wherein the at least one gradient coil set comprises one or more first spiral coils at a first position and one or more second spiral coils at a second position, the first position and the second position being located opposite each other about a center region of the at least one gradient coil set.

89. The method of anyone of embodiments 81-88, wherein the at least one gradient coil set has a rise time less than 10 μs.

90. The method of anyone of embodiments 81-89, wherein the permanent magnet has an aperture through center of the permanent magnet.

91. The method of anyone of embodiments 81-90, further comprising: an electromagnet configured to alter the static magnetic field of the permanent magnet within the region of interest.

92. The method of anyone of embodiments 81-91, wherein the radio frequency receive coil is a flexible coil configured to be affixed to an anatomical portion of a patient for imaging within the region of interest.

93. The method of anyone of embodiments 81-92, wherein the radio frequency receive coil is in one of a single-loop coil configuration, figure-8 coil configuration, or butterfly coil configuration, where the coil is smaller than the region of interest.

94. The method of anyone of embodiments 81-93, wherein the radio frequency transmit coil and the at least one gradient coil set are concentric about the region of interest.

95. The method of embodiment 91, wherein the electromagnet has a magnetic field strength from 10 mT to 1 T.

96. The method of anyone of embodiments 81-95, wherein the magnetic resonance imaging system is a single-sided magnetic resonance imaging system that comprises a magnetic resonance imaging scanner or a magnetic resonance imaging spectrometer.

While this specification contains many specific implementation details, these should not be construed as limitations on the scope of any embodiments or of what may be claimed, but rather as descriptions of features specific to particular implementations of particular embodiments. Certain features that are described in this specification in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

References to “or” may be construed as inclusive so that any terms described using “or” may indicate any of a single, more than one, and all of the described terms. The labels “first,” “second,” “third,” and so forth are not necessarily meant to indicate an ordering and are generally used merely to distinguish between like or similar items or elements.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

1. A magnetic resonance imaging system comprising:
a housing comprising:
a front surface,
a permanent magnet for providing a static magnetic field,
a radio frequency transmit coil, and
a single-sided gradient coil set,
wherein the radio frequency transmit coil and the single-sided gradient coil set are positioned proximate to the front surface;
an electromagnet;
a radio frequency receive coil; and
a power source, wherein the power source is configured to flow current through at least one of the radio frequency transmit coil, the single-sided gradient coil set, or the electromagnet to generate an electromagnetic field in a region of interest, wherein the region of interest resides outside the front surface.

2. The system of claim 1, wherein the radio frequency transmit coil and the single-sided gradient coil set are located on the front surface.

3. The system of claim 1, wherein the front surface is a concave surface.

4. The system of claim 1, wherein the permanent magnet has an aperture through center of the permanent magnet.

5. The system of claim 1, wherein the static magnetic field of the permanent magnet ranges from 1 mT to 1 T.

6. The system of claim 1, wherein the radio frequency transmit coil comprises a first ring and a second ring that are connected via one or more capacitors and/or one or more rungs.

7. The system of claim 1, wherein the radio frequency transmit coil is non-planar and oriented to partially surround the region of interest.

8. The system of claim 1, wherein the single-sided gradient coil set is non-planar and oriented to partially surround the region of interest, and wherein the single-sided gradient coil set is configured to project a magnetic field gradient to the region of interest.

9. The system of claim 1, wherein the single-sided gradient coil set comprises one or more first spiral coils at a first position and one or more second spiral cons at a second position, the first position and the second position being located opposite each other about a center region of the single-sided gradient coil set.

10. The system of claim 1, wherein the single-sided gradient coil set has a rise time less than 10 μs.

11. The system of claim 1, wherein the electromagnet is configured to alter the static magnetic field of the permanent magnet within the region of interest.

12. The system of claim 1, wherein the electromagnet has a magnetic field strength from 10 mT to 1 T.

13. The system of claim 1, wherein the radio frequency receive coil is a flexible coil configured to be affixed to an anatomical portion of a patient for imaging within the region of interest.

14. The system of claim 1, wherein the radio frequency receive coil is in one of a single-loop coil configuration, figure-8 coil configuration, or butterfly coil configuration, wherein the coil is smaller than the region of interest.

15. The system of claim 1, wherein the radio frequency transmit coil and the single-sided gradient coil set are concentric about the region of interest.

16. The system of claim 1, wherein the magnetic resonance imaging system is a single-sided magnetic resonance imaging system that comprises a bore having an opening positioned about a center region of the front surface.

17. A magnetic resonance imaging system comprising:
a housing comprising:
a concave front surface,
a permanent magnet for providing a static magnetic field,
a radio frequency transmit coil, and
at least one gradient coil set,
wherein the radio frequency transmit coil and the at least one gradient coil set are positioned proximate to the concave front surface, wherein the radio frequency transmit coil and the at least one gradient coil set are configured to generate an electromagnetic field in a region of interest, wherein the region of interest resides outside the concave front surface; and
a radio frequency receive coil for detecting signal in the region of interest.

18. The system of claim 17, wherein the radio frequency transmit coil and the at least one gradient coil set are located on the concave front surface.

19. The system of claim 17, wherein the static magnetic field of the permanent magnet ranges from 1 mT to 1 T.

20. The system of claim 17, wherein the static magnetic field of the permanent magnet ranges from 10 mT to 195 mT.

21-96. (canceled)
